(19) United States
(12) Patent Application Publication
(10) Pub. No.: US 2021/0367576 A1
(43) Pub. Date: Nov. 25, 2021

(54) INDUCTORLESS INTERFERENCE CANCELLATION FILTER

(71) Applicant: QUALCOMM INCORPORATED, San Diego, CA (US)

(72) Inventors: Lai Kan LEUNG, San Marcos, CA (US); Aleksandar Miodrag TASIC, San Diego, CA (US); Chiewcharn NARATHONG, Laguna Niguel, CA (US)

(21) Appl. No.: 17/322,647

(22) Filed: May 17, 2021

Related U.S. Application Data
(60) Provisional application No. 63/027,199, filed on May 19, 2020.

(51) Int. Cl. H03H 7/01; H04L 25/03; H03F 3/189

(52) U.S. Cl. CPC H03H 7/0169; H03F 3/189; H04L 25/03261

(57) ABSTRACT

A programmable filter includes a first programmable filter instance comprising a first adjustable active inductance capacitively coupled to a signal receive path, the capacitive coupling comprising at least one adjustable capacitance, the adjustable active inductance and the at least one adjustable capacitance configurable to provide a filter response at a first selected frequency, and a second programmable filter instance comprising a second adjustable active inductance capacitively coupled to the signal receive path, the capacitive coupling comprising at least one adjustable capacitance, the second adjustable active inductance and the at least one adjustable capacitance configurable to provide a filter response at a second selected frequency.

### RELATED APPLICATIONS

This application claims priority to and the benefit of U.S. Provisional Patent Application No. 63/027,199, entitled “INDUCTORLESS INTERFERENCE CANCELLATION FILTER,” filed May 19, 2020, the contents of which are hereby incorporated herein by reference in their entirety as if fully set forth below and for all applicable purposes.

### FIELD

The present disclosure relates generally to electronics, and more specifically to transmitters and receivers in communication devices.

### BACKGROUND

Wireless communication devices and technologies are becoming ever more prevalent. Wireless communication devices generally transmit and receive communication signals. A communication signal is typically processed by a variety of different components and circuits. One of the circuits that process a communication signal is a transceiver. A transceiver may include a transmitter and a receiver. Some wireless communication devices may be configured to operate simultaneously on a variety of different communication bands. For example, a modern wireless communication device may be configured to operate on radio spectrum covering both 5G and 4G LTE frequencies. In some instances, a modern wireless communication device may be configured to operate simultaneously on 5G and 4G LTE frequencies in what can be referred to as carrier aggregation (CA) in which a wireless communication device may simultaneously communicate over multiple carriers.

An example of such a system may be ENDC (E-UTRAN New Radio Dual Connectivity), where a user equipment may simultaneously be in communication with an LTE eNodeB and a 5G gNodeB. When operating in a CA mode over a range of different frequencies, a user equipment has multiple receivers and multiple receive paths in which signals from one receive path may interfere with signals in another receive path.

### SUMMARY

Various implementations of systems, methods and devices within the scope of the appended claims each have several aspects, no single one of which is solely responsible for the desirable attributes described herein. Without limiting the scope of the appended claims, some prominent features are described herein.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

One aspect of the disclosure provides a programmable filter including a first programmable filter instance comprising a first adjustable active inductance capacitively coupled to a signal receive path, the capacitive coupling comprising at least one adjustable capacitance, the adjustable active inductance and the at least one adjustable capacitance configurable to provide a filter response at a first selected frequency, and a second programmable filter instance comprising a second adjustable active inductance capacitively coupled to the signal receive path, the capacitive coupling comprising at least one adjustable capacitance, the second adjustable active inductance and the at least one adjustable capacitance configurable to provide a filter response at a second selected frequency.

Another aspect of the disclosure provides a method for filtering a communication signal including selectively coupling a programmable filter to a signal receive path, setting a first programmable filter instance of the programmable filter to a first frequency, and simultaneously setting a second programmable filter instance of the programmable filter to a second frequency.

Another aspect of the disclosure provides a device including first programmable notch filtering means located between a low noise amplifier (LNA) and a mixer, and second programmable notch filtering means located between the LNA and the mixer. The first programmable notch filtering means may be for filtering a signal at a first frequency selectable based on a first control signal, and the second programmable notch filtering means may be for filtering the signal at a second frequency selectable based on a second control signal.

Another aspect of the disclosure provides a receiver circuit including an antenna coupled to a low noise amplifier (LNA), the LNA coupled to downconversion mixer, a receive filter switchably coupled to the LNA, the receive filter having a first programmable filter instance comprising a first adjustable active inductance capacitively coupled to a signal receive path, the capacitive coupling comprising at least one adjustable capacitance, the adjustable active inductance and the at least one adjustable capacitance configurable to provide a filter response at a first selected frequency, and a second programmable filter instance comprising a second adjustable active inductance capacitively coupled to the signal receive path, the capacitive coupling comprising at least one adjustable capacitance, the second adjustable active inductance and the at least one adjustable capacitance configurable to provide a filter response at a second selected frequency.

Another aspect of the disclosure provides a receiver circuit including a receive path having a low noise amplifier (LNA) and downconversion mixer, the receive path further comprising a plurality of independently reconfigurable notch filter instances coupled in series in the receive path between the LNA and the downconversion mixer.

### BRIEF DESCRIPTION OF THE DRAWINGS

In the figures, like reference numerals refer to like parts throughout the various views unless otherwise indicated. For reference numerals with letter character designations such as “102a” or “102b”, the letter character designations may differentiate two like parts or elements present in the same figure. Letter character designations for reference numerals may be omitted when it is intended that a reference numeral encompass all parts having the same reference numeral in all figures.

FIG. 1 is a diagram showing a wireless device communicating with a wireless communication system.

FIG. 2 is a block diagram showing a wireless device in which exemplary techniques of the present disclosure may be implemented.

FIG. 3 is a simplified block diagram of a receiver circuit.

FIG. 4 is a schematic diagram showing an exemplary embodiment of an implementation of a receive filter in accordance with an exemplary embodiment.

FIG. 5 is a schematic diagram showing an exemplary embodiment of an inductorless interference cancellation filter in accordance with an exemplary embodiment.

FIG. 6 is a schematic diagram of a receiver circuit showing an exemplary embodiment of an implementation of an inductorless interference cancellation filter.

FIG. 7 is a schematic diagram of a receiver circuit showing an exemplary embodiment of an implementation of an inductorless interference cancellation filter.

FIG. 8 is a schematic diagram of a receiver circuit showing an exemplary embodiment of an implementation of an inductorless interference cancellation filter.

FIG. 9 is a schematic diagram showing an exemplary embodiment of an inductorless interference cancellation filter arrangement.

FIG. 10 is a schematic diagram of a receiver circuit showing an exemplary embodiment of an implementation of an inductorless interference cancellation filter.

FIG. 11 is a schematic diagram of a receiver circuit showing an exemplary embodiment of an implementation of an inductorless interference cancellation filter.

FIG. 12 is a schematic diagram showing an exemplary embodiment of an inductorless interference cancellation filter arrangement.

FIG. 13 is a schematic diagram of a receiver circuit showing an exemplary embodiment of an implementation of an inductorless interference cancellation filter.

FIG. 14 is a schematic diagram of a receiver circuit showing an exemplary embodiment of an implementation of an inductorless interference cancellation filter.

FIG. 15 is a flow chart describing an example of the operation of an inductorless interference cancellation filter.

FIG. 16 is a functional block diagram of an apparatus for filtering a received communication signal.

### DETAILED DESCRIPTION

The word “exemplary” is used herein to mean “serving as an example, instance, or illustration.” Any aspect described herein as “exemplary” is not necessarily to be construed as preferred or advantageous over other aspects.

A carrier aggregation (CA) receiver in a communication device may be configured to operate simultaneously over a range of different frequencies. Such a communication device may include multiple receivers in multiple receive paths. It is possible that one or more signals from one receiver or receive path may interfere with signals in another receiver or receive path. For example, depending on the operating frequencies of two receivers, a local oscillator (LO) signal (or harmonics of the LO signal) in one receiver may undergo a frequency transformation due to reciprocal mixing and may appear as an interfering signal having in-band signal energy that may desensitize another receiver or receive path. As another example, an LO signal, or harmonics of an LO signal from a first receive path may be transferred to another receive path via signal coupling and may interfere with the second receive path.

This interference may be mitigated by increasing the isolation between receivers and receive paths or employing frequency dodging, which entails changing the frequency of the VCO (voltage-controlled oscillator). However, increasing the isolation between receivers and receive paths may consume valuable area on the circuit when spacing between the receivers is increased, and frequency dodging may degrade the performance of the VCO by requiring a large frequency tuning range.

Other ways to mitigate the receiver interference include using a harmonic rejection mixer or using digital signal cancellation techniques, both of which may lead to high power consumption and complex digital signal processing.

Exemplary embodiments of the disclosure are directed to an inductorless interference cancellation filter having one or more filter instances that may be simultaneously set to one or more frequencies to create one or more notch filter responses.

Exemplary embodiments of the disclosure are directed to an inductorless interference cancellation filter that may be implemented in an aggressor signal receive path, a victim signal receive path, or in both an aggressor signal receive path and a victim signal receive path.

Exemplary embodiments of the disclosure are directed to an inductorless interference cancellation filter that may be selectively coupled to an aggressor signal receive path, a victim signal receive path, or selectively coupled to both an aggressor signal receive path and a victim signal receive path.

Exemplary embodiments of the disclosure are directed to an inductorless interference cancellation filter that may be selectively coupled to a low noise amplifier (LNA), and/or to an internal or interface LNA (iLNA), in an implementation where an LNA may be located separate from an iLNA.

Exemplary embodiments of the disclosure are directed to an inductorless interference cancellation filter that may be implemented in a carrier aggregation (CA) receiver having a plurality of signal communication bands.

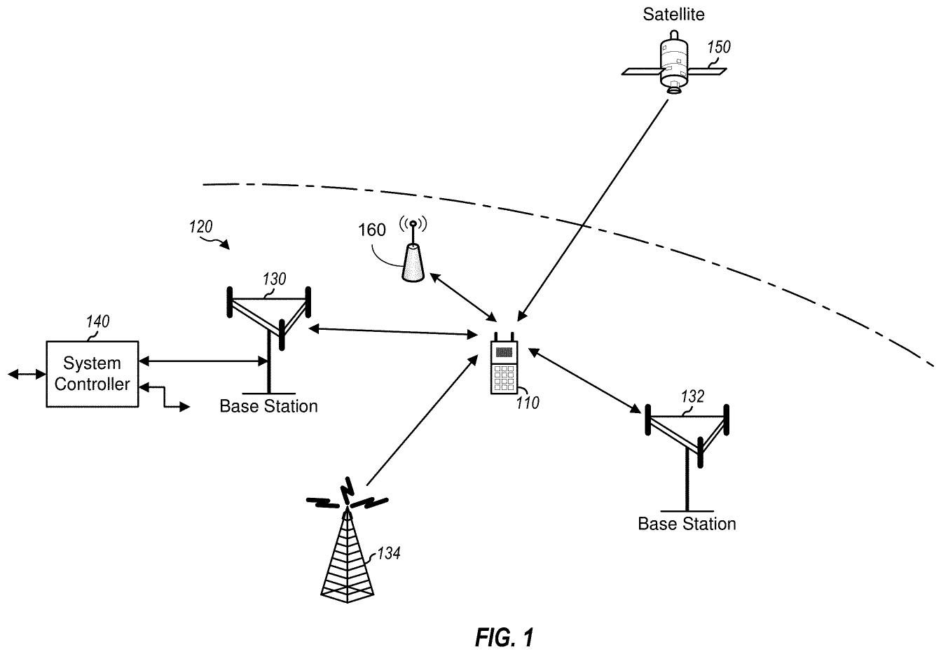

FIG. 1 is a diagram showing a wireless device 110 communicating with a wireless communication system 120. The wireless communication system 120 may be a 5G NR (new radio) system, Long Term Evolution (LTE) system, a Code Division Multiple Access (CDMA) system, a Global System for Mobile Communications (GSM) system, a wireless local area network (WLAN) system, a 5G system, or some other wireless system. A CDMA system may implement Wideband CDMA (WCDMA), CDMA 1×, Evolution-Data Optimized (EVDO), Time Division Synchronous CDMA (TD-SCDMA), or some other version of CDMA. For simplicity, FIG. 1 shows wireless communication system 120 including two base stations 130 and 132 and one system controller 140. In general, a wireless communication system may include any number of base stations and any set of network entities.

The wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a tablet, a cordless phone, a medical device, a device configured to connect to one or more other devices (for example through the internet of things), a wireless local loop (WLL) station, a Bluetooth device, etc. Wireless device 110 may communicate with wireless communication system 120. Wireless device 110 may also receive signals from broadcast stations (e.g., a broadcast station 134), signals from satellites (e.g., a satellite 150) in one or more global navigation satellite systems (GNSS), etc. Wireless device 110 may support one or more radio technologies for wireless communication such as 5G NR, LTE, WCDMA, CDMA 1×, EVDO, TD-SCDMA, GSM, 802.11, 5G, Bluetooth, 802.15, etc.

Wireless device 110 may support carrier aggregation, for example as described in one or more LTE or 5G standards. In some embodiments, a single stream of data is transmitted over multiple carriers using carrier aggregation, for example as opposed to separate carriers being used for respective data streams.

Wireless device 110 may be able to operate in low-band (LB) covering frequencies lower than 1000 megahertz (MHz), mid-band (MB) covering frequencies from 1000 MHz to 2300 MHz, and/or high-band (HB) covering frequencies higher than 2300 MHz. For example, low-band may cover 698 to 960 MHz, mid-band may cover 1475 to 2170 MHz, and high-band may cover 2300 to 2690 MHz and 3400 to 5000 MHz. Low-band, mid-band, and high-band refer to three groups of bands (or band groups), with each band group including a number of frequency bands (or simply, “bands”). Each band may cover up to 200 MHz and may include one or more carriers in certain systems. For example, each carrier may cover up to 20 MHz in LTE. LTE Release 11 supports 35 bands, which are referred to as LTE/UMTS bands and are listed in 3GPP TS 36.101. Wireless device 110 may be configured with up to five carriers in one or two bands in LTE Release 11. Wireless device 110 may further be able to operate at frequencies higher than 5000 MHz, for example at frequencies up to 6-7 GHz and/or at mmw frequencies (e.g., frequencies at or above approximately 24 GHZ).

The wireless device 110 may also be in communication with a wireless device 160. In an exemplary embodiment, the wireless device 160 may be a wireless access point, or another wireless communication device that comprises, or comprises part of a wireless local area network (WLAN). An exemplary embodiment of a WLAN signal may include WiFi, or other communication signals that use unlicensed communication spectrum in the range of, for example, 2 GHz to 6 GHz or mmw frequencies. The wireless device 110 may also be capable of ENDC (E-UTRAN New Radio Dual Connectivity), where the wireless device 110 may simultaneously be in communication with a first base station (for example, an eNodeB, which may be operating pursuant to a first radio access technology, such as LTE) and with a second base station (for example, a gNodeB, which may be operating pursuant to a second radio access technology, such as 5G). The wireless device 110 may additionally or instead communicate directly with another wireless device 110.

In general, carrier aggregation (CA) may be categorized into two types—intra-band CA and inter-band CA. Intra-band CA refers to operation on multiple carriers within the same band. Inter-band CA refers to operation on multiple carriers in different bands.

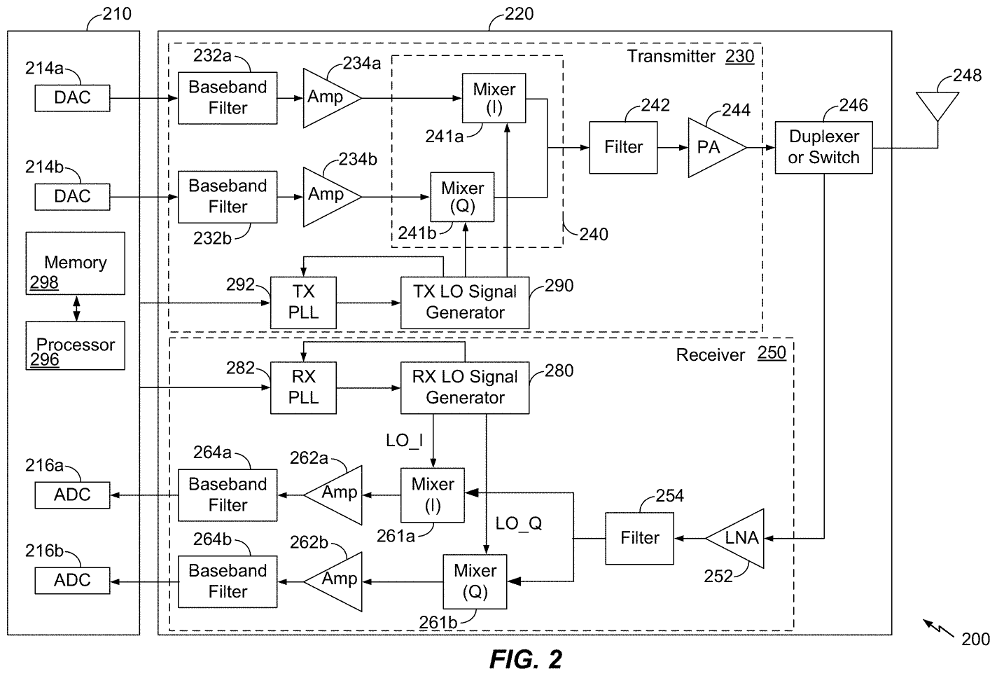

FIG. 2 is a block diagram showing a wireless device 200 in which the exemplary techniques of the present disclosure may be implemented. FIG. 2 shows an example of a transceiver 220. In general, the conditioning of the signals in a transmitter 230 and a receiver 250 may be performed by one or more stages of amplifier, filter, upconverter, downconverter, etc. These circuit blocks may be arranged differently from the configuration shown in FIG. 2. Furthermore, other circuit blocks not shown in FIG. 2 may also be used to condition the signals in the transmitter 230 and receiver 250. Unless otherwise noted, any signal in FIG. 2, or any other figure in the drawings, may be either single-ended or differential. Some circuit blocks in FIG. 2 may also be omitted.

In the example shown in FIG. 2, wireless device 200 generally comprises a transceiver 220 and a data processor 210. The data processor 210 may include a processor 296 operatively coupled to a memory 298. The memory 298 may be configured to store data and program codes, and may generally comprise analog and/or digital processing elements. In some embodiments, the processor 296 and memory 298 may execute logic to operate and/or control some of the functionality of the inductorless interference cancellation filter described herein. The transceiver 220 includes a transmitter 230 and a receiver 250 that support bi-directional communication. In general, wireless device 200 may include any number of transmitters and/or receivers for any number of communication systems and frequency bands. All or a portion of the transceiver 220 may be implemented on one or more analog integrated circuits (ICs), RF ICs (RFICs), mixed-signal ICs, etc.

A transmitter or a receiver may be implemented with a super-heterodyne architecture or a direct-conversion architecture. In the super-heterodyne architecture, a signal is frequency-converted between radio frequency (RF) and baseband in multiple stages, e.g., from RF to an intermediate frequency (IF) in one stage, and then from IF to baseband in another stage for a receiver. In the direct-conversion architecture, a signal is frequency converted between RF and baseband, or near baseband, in one stage. The super-heterodyne and direct-conversion architectures may use different circuit blocks and/or have different requirements. In the example shown in FIG. 2, transmitter 230 and receiver 250 are implemented with the direct-conversion architecture, but those of skill in the art will understand that the inductorless interference cancellation filter described herein may also be used in a super-heterodyne architecture.

In the illustrated transmit path, the data processor 210 processes data to be transmitted and provides in-phase (I) and quadrature (Q) analog output signals to the transmitter 230. In an exemplary embodiment, the data processor 210 includes digital-to-analog-converters (DAC's) 214a and 214b for converting digital signals generated by the data processor 210 into the I and Q analog output signals, e.g., I and Q output currents, for further processing. In other embodiments, the DACs 214a and 214b are included in the transceiver 220 and the data processor 210 provides data (e.g., for I and Q) to the transceiver 220 digitally.

Within the transmitter 230, lowpass filters 232a and 232b filter the I and Q analog transmit signals, respectively, to remove undesired images caused by the prior digital-to-analog conversion Amplifiers (Amp) 234a and 234b amplify the signals from lowpass filters 232a and 232b, respectively, and provide I and Q baseband signals. An upconverter 240 upconverts the I and Q baseband signals (e.g., using mixers 241a, 241b) with I and Q transmit (TX) local oscillator (LO) signals from a TX LO signal generator 290 and provides an upconverted signal. A filter 242 filters the upconverted signal to remove undesired images caused by the frequency upconversion as well as noise in a receive frequency band. A power amplifier (PA) 244 amplifies the signal from filter 242 to obtain the desired output power level and provides a transmit RF signal. The transmit RF signal may be routed through a duplexer or switch 246 and transmitted via an antenna 248.

The power amplifier 244 may comprise one or more stages comprising, for example, driver stages, power amplifier stages, or other components, that can be configured to amplify a communication signal on one or more frequencies, in one or more frequency bands, and at one or more power levels. Depending on various factors, the power amplifier 244 can be configured to operate using one or more bias signals and can be configured in various topologies or architectures.

In the receive path, antenna 248 receives communication signals and provides a received RF signal, which may be routed through duplexer or switch 346 and provided to a low noise amplifier (LNA) 252. The duplexer 246 is designed to operate with a specific RX-to-TX duplexer frequency separation, such that RX signals are isolated from TX signals. The received RF signal is amplified by LNA 252 and filtered by a filter 254 to obtain a desired RF input signal. Downconversion mixers 261a and 261b mix the output of filter 254 with I and Q receive (RX) LO signals (i.e., LO_I and LO_Q) from an RX LO signal generator 280 to generate I and Q baseband signals. The I and Q baseband signals are amplified by amplifiers 262a and 262b and further filtered by lowpass filters 264a and 264b to obtain I and Q analog input signals, which are provided to data processor 210. In the exemplary embodiment shown, the data processor 210 includes analog-to-digital-converters (ADC's) 216a and 216b for converting the analog input signals into digital signals to be further processed by the data processor 210. In some embodiments, the ADCs 216a and 216b are included in the transceiver 220 and provide data to the data processor 210 digitally. One or more exemplary embodiments of an inductorless interference cancellation filter may be implemented in the filter 254 of FIG. 2. An inductorless interference cancellation filter may also or alternatively be implemented in other locations within the transceiver 220.

In FIG. 2, TX LO signal generator 290 generates the I and Q TX LO signals used for frequency upconversion, while RX LO signal generator 280 generates the I and Q RX LO signals used for frequency downconversion. Each LO signal is a periodic signal with a particular fundamental frequency. A phase locked loop (PLL) 292 receives timing information from data processor 210 and generates a control signal used to adjust the frequency and/or phase of the TX LO signals from LO signal generator 290. Similarly, a PLL 282 receives timing information from data processor 210 and generates a control signal used to adjust the frequency and/or phase of the RX LO signals from LO signal generator 280.

Wireless device 200 may support CA and may (i) receive multiple downlink signals transmitted by one or more cells on multiple downlink carriers at different frequencies and/or (ii) transmit multiple uplink signals to one or more cells on multiple uplink carriers. Those of skill in the art will understand, however, that aspects described herein may be implemented in systems, devices, and/or architectures that do not support carrier aggregation.

Certain elements of the transceiver 220 are functionally illustrated in FIG. 2, and the configuration illustrated therein may or may not be representative of a physical device configuration in certain implementations. For example, as described above, transceiver 220 may be implemented in various integrated circuits (ICs), RF ICs (RFICs), mixed-signal ICs, etc. In some embodiments, the transceiver 220 is implemented on a substrate or board such as a printed circuit board (PCB) having various modules. For example, the PA 244, the filter 242, and the duplexer 246 may be implemented in separate modules or as discrete components, while the remaining elements illustrated in the transceiver 220 may be implemented in a single transceiver chip. Further, while FIG. 2 illustrates I and Q signals, those of skill in the art will understand that the transceiver 220 may alternatively be implemented using a polar architecture or may include elements to implement a polar architecture in addition to a quadrature architecture.

Exemplary embodiments of the disclosure are directed to an inductorless interference cancelling filter that may be implemented to create one or more notch responses. Such filter and notch response may be used to mitigate the effect of receive path interference.

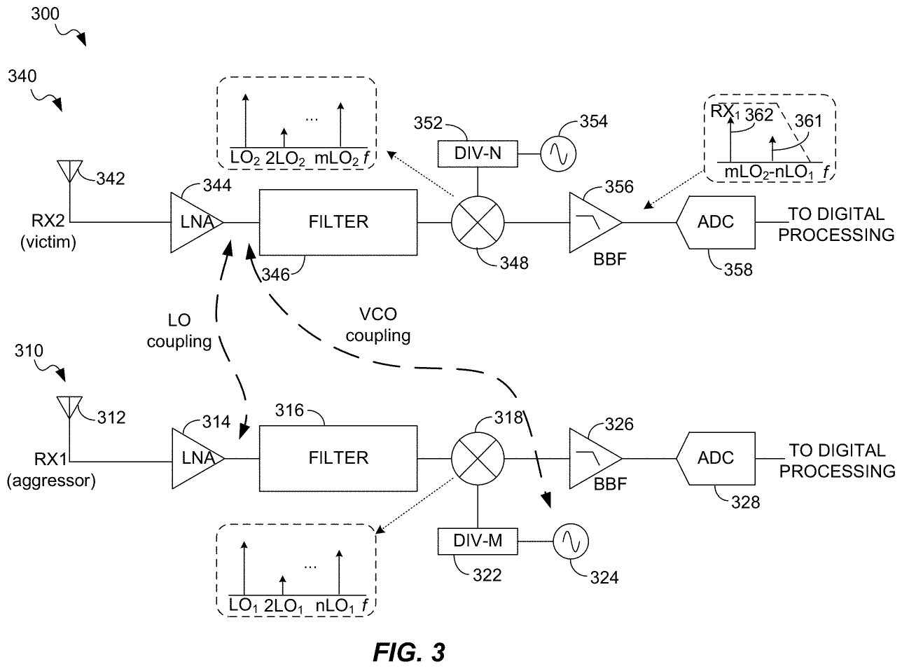

FIG. 3 is a simplified block diagram of a receiver circuit 300. In an exemplary embodiment, the receiver circuit 300 includes a first receive path 310 and a second receive path 340. In an exemplary embodiment, the receive path 310 may be referred to as RX1 and may be considered for this example as having an aggressor signal. In an exemplary embodiment, the receive path 340 may be referred to as RX2 and may be considered for this example a victim of an aggressor signal.

In an exemplary embodiment, the first receive path 310 may include an antenna 312, a low noise amplifier (LNA) 314, a filter 316, a mixer 318, a divider 322, a voltage-controlled oscillator 324, a baseband filter (BBF) 326 and an analog-to-digital converter (ADC) 328. The divider 322 may, in this example, be a divide-by-M (DIV/M) divider capable of integer division or fractional division.

In an exemplary embodiment, the second receive path 340 may include an antenna 342, a low noise amplifier (LNA) 344, a filter 346, a mixer 348, a divider 352, a voltage-controlled oscillator 354, a baseband filter (BBF) 356 and an analog-to-digital converter (ADC) 358. The divider 352 may, in this example, be a divide-by-N(DIV/N) divider capable of integer division or fractional division.

The antennas 312, 342 may be example implementations of the antenna 248 of FIG. 2. The LNAs 312, 342 may be example implementations of the LNA 252. The filters 316, 346 may be example implementations of the filter 254. The mixers 318, 348 may be example implementations of the mixers 261. The BBFs 326, 356 may be example implementations of the filters 264. The ADCs 328, 358 may be example implementations of the ADCs 216. Outputs of the ADCs 328, 358 may be processed by the data processor 210 and/or the processor 296. The dividers 322, 352 and the voltage-controlled oscillators 324, 354 may be example implementations of the PLL 282 and LO signal generator 280 of FIG. 2. Unless described otherwise, elements in FIG. 3 are similar in operation to corresponding elements in FIG. 2 and will not be again described in detail.

In some embodiments, all of the elements illustrated in FIG. 3 except for the antennas 312, 342 are implemented on the same chip. For example, inputs of the LNAs 314, 344 may be coupled to respective chip inputs. In other embodiments, one or both of the LNAs 314, 344, and/or one or both of the filters 316, 346 are implemented external to the chip and an output(s) thereof is coupled to the chip input(s). Similarly, outputs of the ADCs 328, 358 may be coupled to respective chip outputs or combined and provided to a common chip output.

In an exemplary embodiment, a signal in one of the first receive path 310 or the second receive path 340 may interfere with the reception of a communication signal in the other of the first receive path 310 or the second receive path 340.

For example, an LO signal generated by the VCO 324 in the first receive path 310 may appear at the input of the filter 346 in the second receive path. Similarly, a signal at the input of the filter 316 in the first receive path 310 may couple via one or more on-board (or on-chip) coupling mechanisms (such as electromagnetic (EM) coupling occurring via signal routing lines), to the input of the filter 346 in the second receive path 340, and a signal at the input of the filter 346 in the second receive path 340 may couple via one or more on-board (or on-chip) coupling mechanisms to the input of the filter 316 in the first receive path 310.

For example, a harmonic, nLO₁ of the LO signal generated in the mixer 318 may mix with a harmonic mLO₂ of the LO signal generated in the mixer 348 and appear in the RX1 receive band at the output of the BBF 356 at a frequency of mLO₂-nLO₁. This signal 361 may interfere with a communication signal 362 in the RX2 signal band of the second receive path 340. As shown in FIG. 3, the signal 361 may be within a passband of the BBF 356 and thus may be interpreted as being part of the communication signal 362, which may result in inaccurate processing and/or interpretation of the signal 362. In some embodiments, the signal 361 is much stronger than the signal 362, which may cause the signal 362 to be masked or ignored during processing. Filtering out the harmonic nLO₁ (e.g., using the filter 346) prior to the downconversion process, or filtering out the signal 361 prior to it being passed to the ADC 358, would therefore be beneficial.

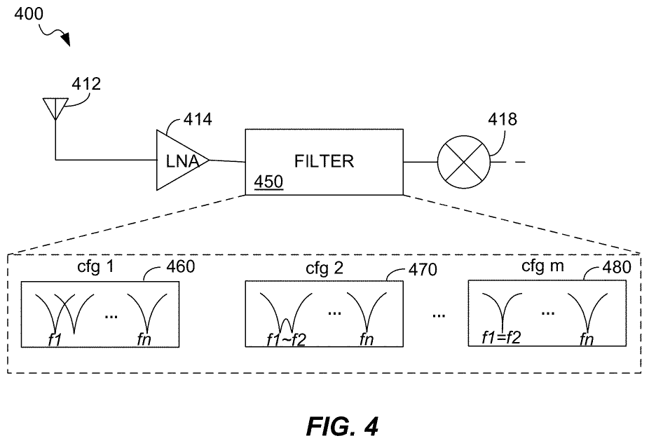

FIG. 4 is a schematic diagram 400 showing an exemplary embodiment of an implementation of a receive filter in accordance with an exemplary embodiment. An antenna 412, LNA 414 and mixer 418 are shown for reference, and are similar to the antenna 312, LNA 314 and mixer 318 of FIG. 3. In an exemplary embodiment, an inductorless interference cancellation filter 450 may be implemented to have one or more different programmable configurations with corresponding different filter responses. Further, multiple instances of the inductorless interference cancellation filter 450 may be implemented to create one or more configurations having one or more filter responses at one or more frequencies.

For example, in a first exemplary configuration 460, the inductorless interference cancellation filter 450 may be configured with one or more programmable notch responses located at one or more different programmable frequencies, f1 through fn.

In another exemplary configuration 470, a first notch frequency, f1, and a second notch frequency, f2, may be set to frequencies that are close together, thus creating a stop band that spans the first notch frequency, f1, and the second notch frequency, f2, thus extending the frequency range of the stop band. An example of setting f1 and f2 close in frequency to create a stop band that spans the first notch frequency, f1, and the second notch frequency, f2, may occur in a case where (f2−f1) is within the frequency range of the communication band in which a victim receiver operates, for example, 70 MHz in band B7.

In another exemplary configuration 480, a first notch frequency, f1, and a second notch frequency, f2, may be set to the same frequency, thus strengthening the attenuation at the selected frequency, which may also be referred to as “deepening the notch.” Although described in FIG. 4 as having three exemplary configurations 460, 470 and 480, the inductorless interference cancellation filter 450 may be configured to have more or fewer configurations. Further, while the configurations illustrate notches in addition to f1 and f2, such additional notches may be omitted in some embodiments or additional notches may be implemented.

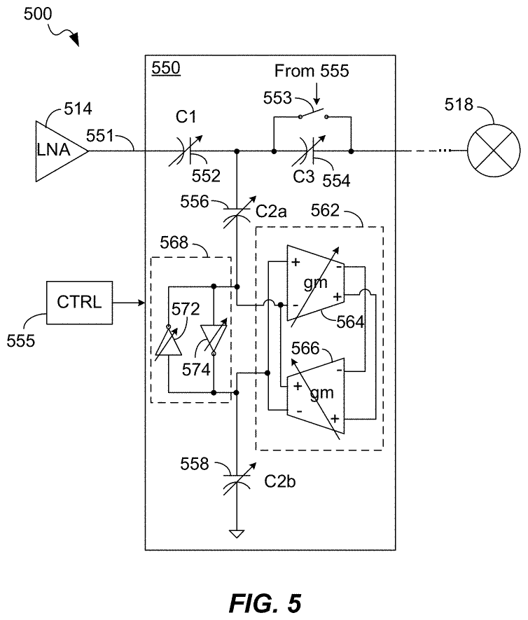

FIG. 5 is a schematic diagram 500 showing an exemplary embodiment of an inductorless interference cancellation filter 550 in accordance with an exemplary embodiment. The diagram 500 shows an example LNA 514, an inductorless interference cancellation filter 550 and a mixer 518. The LNA 514 and the mixer 518 are similar to the LNAs and mixers described in FIG. 4.

In an exemplary embodiment, an inductorless interference cancellation filter 550 may comprise adjustable capacitances 552, 554, 556 and 558, a switch 553 located around the adjustable capacitance 554; an active gyrator circuit 562 and a Q-boost circuit 568. In an exemplary embodiment, the adjustable capacitance 552 may be configured as a programmable DC blocking capacitance.

In an exemplary embodiment, the active gyrator circuit 562 may comprise a gain (gm, or transconductance) stage 564 and a gm (transconductance) stage 566. In an exemplary embodiment, the Q-boost circuit 568 may comprise an inverter 572 and an inverter 574. The inverters 572 and 574 may be configured to provide an adjustable negative gm. In an exemplary embodiment, the active gyrator circuit 562 may be configured to provide an adjustable inductance (also referred to as an adjustable active inductance) without a discrete inductor or discrete inductive element. In an exemplary embodiment, the active gyrator circuit 562 may be configured as a differential circuit as shown in FIG. 5, or may be configured as a single-ended circuit. When configured as a differential circuit as shown in FIG. 5, the adjustable capacitor 556 and the adjustable capacitor 558 are used to capacitively couple the active gyrator circuit 562 to the signal receive path between the output of the LNA 514 on connection 551 and system ground. When the active gyrator circuit 562 is implemented as a single-ended circuit, only one of the adjustable capacitances 556 or 558 would be used to capacitively couple the active gyrator circuit 562 to the signal receive path and ground.

In an exemplary embodiment, when the switch 553 is open, the adjustable capacitance 552, the adjustable capacitance 554, the adjustable capacitance 556 and the adjustable capacitance 558 together with the inductance selected by the programming of the active gyrator circuit 562 may be used to set the operating frequency of the inductorless interference cancellation filter 550.

In an exemplary embodiment, when the switch 553 is closed and the adjustable capacitance 554 is bypassed, the value of the adjustable capacitance 552 and the adjustable capacitance 556 together with the inductance selected by the programming of the active gyrator circuit 562 may be used to set the operating frequency of the inductorless interference cancellation filter 550. In some embodiments, for example embodiments in which high-pass filtering is not required or desired, the switch 553 and the capacitance 554 are omitted.

In an exemplary embodiment, the Q-boost circuit 568 may be configured to increase or otherwise influence the inductance developed by the active gyrator circuit 562. In an exemplary embodiment, the Q-boost circuit 568 may be configured to establish a back-to-back negative gm. The inverters 572 and 574 in the Q-boost circuit 568 are connected back-to-back, thus creating a negative gm value, which can then cancel the loss of the notch filter formed by the active gyrator circuit 562 and the capacitances 552, 554, 556 and 558. In this manner, the quality factor (Q) of the inductorless interference cancellation filter 550 may be increased (or boosted). In other embodiments, the Q-boost circuit 568 is omitted, for example in embodiments in which performance is sufficient without the Q-boost circuit 568.

In an exemplary embodiment, the inductorless interference cancellation filter 550 may be configured to provide a notch filter response at a variety of different frequencies, depending on the values selected for the adjustable capacitances 552, 554, 556 and 558; and the active gyrator circuit 562.

In an exemplary embodiment, the control signals used to determine the values of the adjustable capacitances 552, 554, 556 and 558; the inverters 572 and 574; and the active gyrator circuit 562, as well as control the state of the switch 553 may be generated by a controller 555 or by the data processor 210 of FIG. 2. In an exemplary embodiment, the controller 555 may be part of the data processor 210 of FIG. 2, or may be another control element. For example, the controller 555 may be implemented digitally on the chip on which the LNA 514, filter 550, and mixer 518 are implemented. Such controller 555 may be in communication with the data processor 210.

In an exemplary embodiment, “n” notch filter responses can be created to attenuate “n” (or fewer) different spurious signals in each receive path. The active gyrator circuit 562 may be programmable by adjusting a DC bias, or by slicing units. The term “slicing units” refers to the gm stage 564 and gm stage 566 being implemented using multiple small gm units. In such an implementation, the total effective gm (or the effective inductance of the active gyrator circuit 562) can be changed by enabling a different number of these small gm units. In some embodiments, the DC bias for the gyrator circuit 562 may be relatively low, thereby enabling operation of the inductorless interference cancellation filter 550 at a relatively low power. Implementing a notch filter using the gyrator circuit 562 instead of a discrete inductor or coil (and using one or more capacitances, for example to create an LC response without the discrete inductor or coil) may result in small area and add no extra EM coupling path.

The inductorless interference cancellation filter 550 can be programmed with different configurations, for example based on carrier-aggregation (CA) band combination, i.e., no band-combination-specific design is mandated. In an exemplary embodiment, the adjustable capacitances 552, 554, 556 and 558; and the active gyrator circuit 562 may be programmed to create one or more notch filter responses to attenuate one or more spurious signals at one or more frequencies.

In an exemplary embodiment, the Q-boost circuit 568 may be programmed to adjust the notch depth. For example, the total negative gm of the Q-boost circuit 568 can be programmed by changing the DC bias of the inverters 572 and 574, or by enabling a different number of small inverter units.

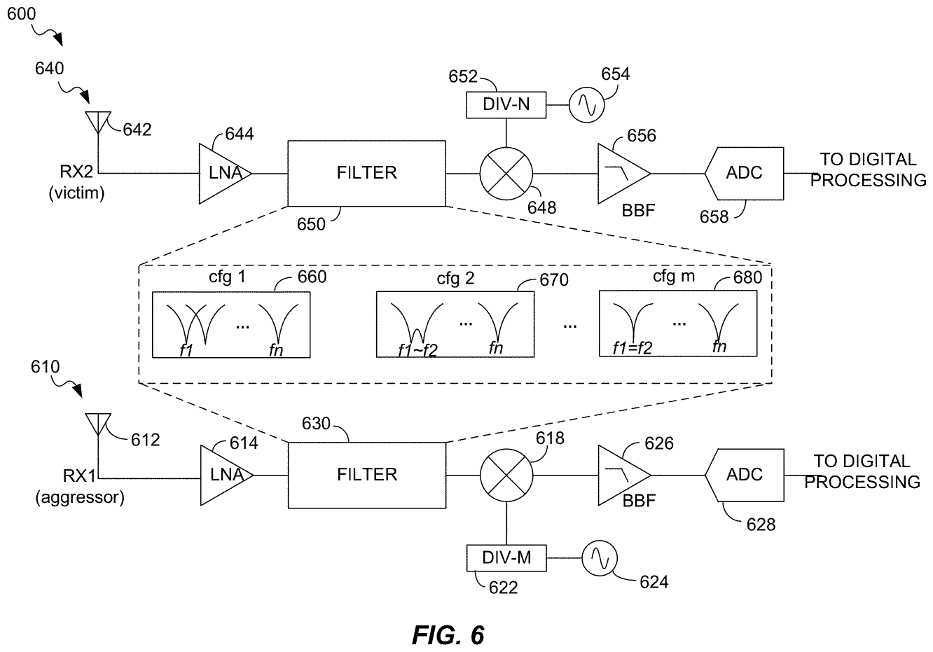

FIG. 6 is a schematic diagram of a receiver circuit 600 showing an exemplary embodiment of an implementation of an inductorless interference cancellation filter. In an exemplary embodiment, the receiver circuit 600 includes a first receive path 610 and a second receive path 640. In an exemplary embodiment, the first receive path 610 may be referred to as RX1 and may be considered for this example as generating an aggressor signal. In an exemplary embodiment, the receive path 640 may be referred to as RX2 and may be considered for this example a victim of an aggressor signal.

In an exemplary embodiment, the first receive path 610 may include an antenna 612, a low noise amplifier (LNA) 614, a filter 630, a mixer 618, a divider 622, a voltage-controlled oscillator 624, a baseband filter (BBF) 626 and an analog-to-digital converter (ADC) 628. The divider 622 may, in this example, be a divide-by-M (DIV/M) divider capable of integer division or fractional division.

In an exemplary embodiment, the second receive path 640 may include an antenna 642, a low noise amplifier (LNA) 644, a filter 650, a mixer 648, a divider 652, a voltage-controlled oscillator 654, a baseband filter (BBF) 656 and an analog-to-digital converter (ADC) 658. The divider 652 may, in this example, be a divide-by-N(DIV/N) divider capable of integer division or fractional division. Although the circuit 600 is described in FIG. 6 as having two receive paths 610 and 640, it should be understood that the receiver circuit 600 may include more of fewer receive paths.

The antennas 612, 642 may be example implementations of the antenna 248 of FIG. 2. The LNAs 614, 644 may be example implementations of the LNA 252. The filters 630, 650 may be example implementations of the filter 254. The mixers 618, 648 may be example implementations of the mixers 261. The BBFs 626, 656 may be example implementations of the filters 264. The ADCs 628, 658 may be example implementations of the ADCs 216. Outputs of the ADCs 628, 658 may be processed by the data processor 210 and/or the processor 296. The dividers 622, 652 and the voltage-controlled oscillators 624, 654 may be example implementations of the PLL 282 and LO signal generator 280 of FIG. 2. Unless described otherwise, elements in FIG. 6 are similar in operation to corresponding elements in FIG. 2 and will not be again described in detail.

In some embodiments, all of the elements illustrated in FIG. 6 except for the antennas 612, 642 are implemented on the same chip. For example, inputs of the LNAs 614, 644 may be coupled to respective chip inputs. In other embodiments, one or both of the LNAs 614, 644, and/or one or both of the filters 630, 650 are implemented external to the chip and an output(s) thereof is coupled to the chip input(s). Similarly, outputs of the ADCs 628, 658 may be coupled to respective chip outputs or combined and provided to a common chip output.

In an exemplary embodiment, a signal in one of the first receive path 610 or the second receive path 640 may interfere with the reception of a communication signal in a receive band of the other of the first receive path 610 or the second receive path 640.

In an exemplary embodiment, each of the first receive path 610 and the second receive path 640 may implement one or more instances of an inductorless interference cancellation filter in accordance with an exemplary embodiment of the disclosure.

For example, the first receive path 610 may implement an inductorless interference cancellation filter 630 and the second receive path 640 may implement an inductorless interference cancellation filter 650.

For example, each of the first receive path 610 and the second receive path 640 may implement one or more configurations of an inductorless interference cancellation filter. For example, in a first exemplary configuration 660, each of the inductorless interference cancellation filters 630 and 650 may be configured with one or more programmable notch responses located at one or more different programmable frequencies, f1 through fn. The notch responses programmed in 630 and 650 may be the same, partially the same, or different (e.g., same or different in frequency and/or number of notches).

In another exemplary configuration 670, a first notch frequency, and a second notch frequency, f2, may be set to frequencies that are close together, thus extending the frequency range of a stop band.

In another exemplary configuration 680, a first notch frequency, and a second notch frequency, f2, may be set to the same frequency, thus strengthening the attenuation at the selected frequency, which may also be referred to as “deepening the notch.” Although described in FIG. 6 as having three exemplary configurations 660, 670 and 680, the inductorless interference cancellation filter 630 and the inductorless interference cancellation filter 650 may be configured to have more or fewer configurations. Moreover, the exemplary configurations of the inductorless interference cancellation filter 630 may be different than the exemplary configurations of the inductorless interference cancellation filter 650.

In some embodiments, no inductors or coils are coupled in the signal path between the input of the LNA 614 and/or 644 (or the respective chip inputs coupled to these LNAs), and the output of the ADC 628 and/or 658 (or the chip output(s) coupled to these ADCs), respectively. In some such embodiments, no inductors or coils are connected to any of the illustrated components, with the exception of the oscillator 624/654, in the chip.

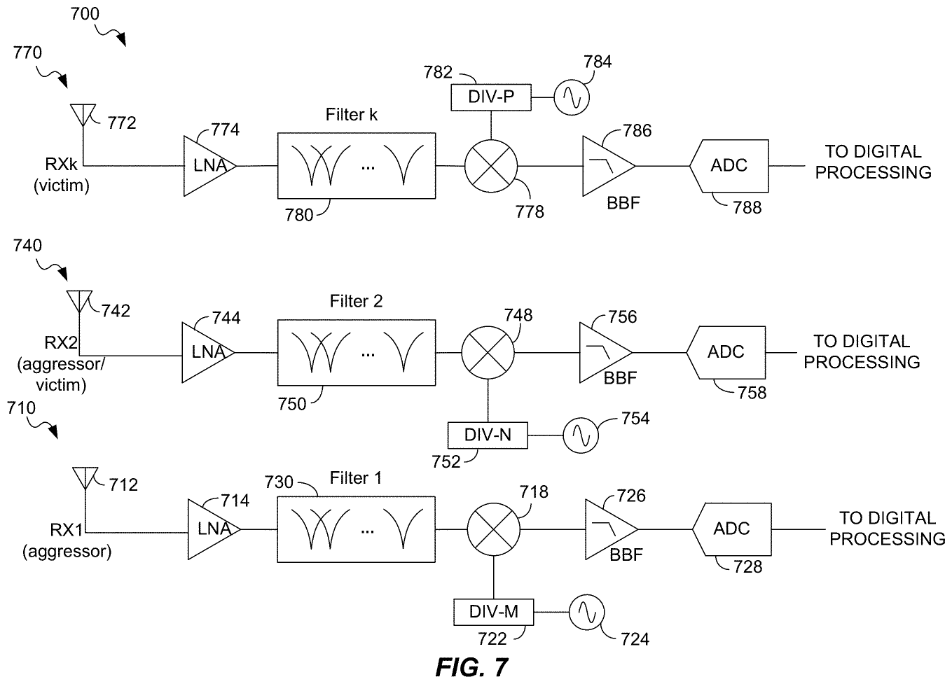

FIG. 7 is a schematic diagram of a receiver circuit 700 showing an exemplary embodiment of an implementation of an inductorless interference cancellation filter. In an exemplary embodiment, the receiver circuit 700 includes a first receive path 710, a second receive path 740 and a third receive path 770. In an exemplary embodiment, the first receive path 710 may be referred to as RX1 and may be considered for this example as generating an aggressor signal. In an exemplary embodiment, the second receive path 740 may be referred to as RX2 and may be considered for this example as generating an aggressor signal and also being a victim of another aggressor signal. In an exemplary embodiment, the third receive path 770 may be referred to as RXk and may be considered for this example a victim of an aggressor signal.

In an exemplary embodiment, the first receive path 710 may include an antenna 712, a low noise amplifier (LNA) 714, a filter 730, a mixer 718, a divider 722, a voltage-controlled oscillator 724, a baseband filter (BBF) 726 and an analog-to-digital converter (ADC) 728. The divider 722 may, in this example, be a divide-by-M (DIV/M) divider capable of integer division or fractional division.

In an exemplary embodiment, the second receive path 740 may include an antenna 742, a low noise amplifier (LNA) 744, a filter 750, a mixer 748, a divider 752, a voltage-controlled oscillator 754, a baseband filter (BBF) 756 and an analog-to-digital converter (ADC) 758. The divider 752 may, in this example, be a divide-by-N(DIV/N) divider capable of integer division or fractional division.

In an exemplary embodiment, the third receive path 770 may include an antenna 772, a low noise amplifier (LNA) 774, a filter 780, a mixer 778, a divider 782, a voltage-controlled oscillator 784, a baseband filter (BBF) 786 and an analog-to-digital converter (ADC) 788. The divider 782 may, in this example, be a divide-by-P (DIV/P) divider capable of integer division or fractional division. Elements in FIG. 7 may be similar in operation to corresponding elements in FIGS. 2 and 6, and will not be again described in detail. Although described in FIG. 7 as having three receive paths 710, 740 and 770, it should be understood that the receiver circuit 700 may include more of fewer receive paths.

In an exemplary embodiment, it is desirable to reduce the strength (or remove) the spurious signal energy falling in-band prior to down-conversion, that is, before a mixer. In an exemplary embodiment, a first inductorless interference cancellation filter 730 (filter 1) may include one or more filter instances that may be implemented before the mixer 718 (i.e., signal down-conversion) in the first receive path 710 to attenuate (shunt away) an aggressor spurious signal at a first frequency.

In an exemplary embodiment, a second inductorless interference cancellation filter 750 (filter 2) may include one or more filter instances that may be implemented before the mixer 748 (i.e., signal down-conversion) in the second receive path 740 to attenuate (shunt away) a victim spurious signal at the first frequency. In an exemplary embodiment, the second inductorless interference cancellation filter 750 (filter 2) may include one or more filter instances that may also be configured to attenuate aggressor spurious signal energy at a second frequency.

In an exemplary embodiment, a third (kth) inductorless interference cancellation filter 780 (filter k) may include one or more filter instances that may be implemented before the mixer 778 (i.e., signal down-conversion) in the third receive path 770 to attenuate the victim spurious signal energy at the first frequency and/or second frequency.

In another exemplary embodiment, each of the inductorless interference cancellation filters 730, 750 and 780 can also or alternatively be used to attenuate signal energy leaked from transmitters, i.e., TX jammers.

In configurations described in this disclosure that include an inductorless interference cancellation filter, the entire signal path between a chip input and chip output which includes the inductorless cancellation filter may be inductorless/coil-less, for example as described with respect to FIG. 6. In some embodiments, there are no inductors or coils (including transformers) in the signal path between a chip input and the output of the inductorless interference cancellation filter.

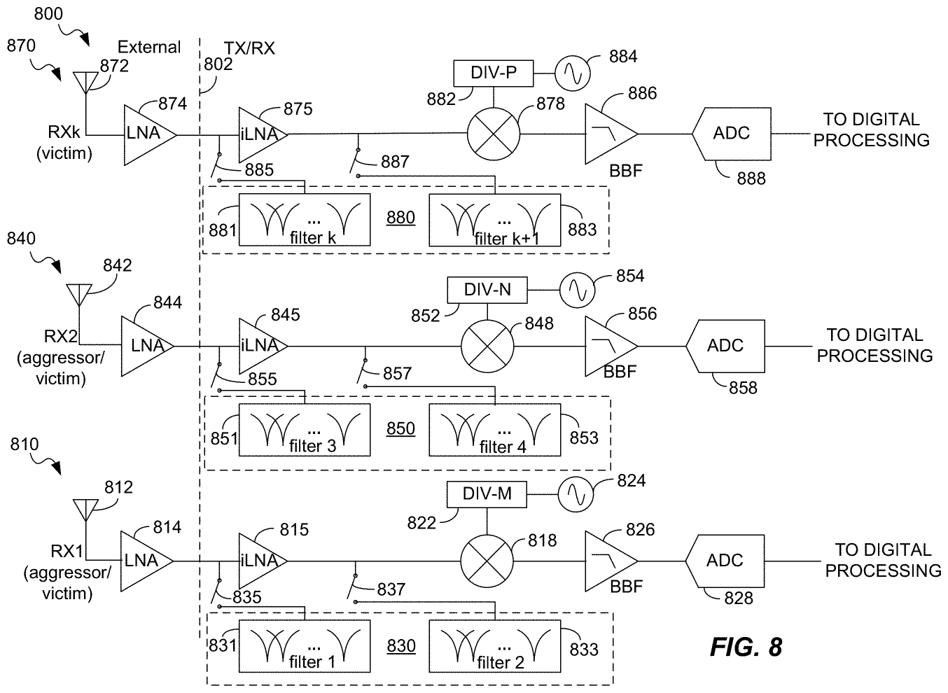

FIG. 8 is a schematic diagram of a receiver circuit 800 showing an exemplary embodiment of an implementation of an inductorless interference cancellation filter. In an exemplary embodiment, the receiver circuit 800 includes a first receive path 810, a second receive path 840 and a third receive path 870. In an exemplary embodiment, the first receive path 810 may be referred to as RX1 and may be considered for this example as generating an aggressor signal and/or as being a victim of another aggressor signal. In an exemplary embodiment, the second receive path 840 may be referred to as RX2 and may be considered for this example as generating an aggressor signal and/or as being a victim of another aggressor signal. In an exemplary embodiment, the third receive path 870 may be referred to as RXk and may be considered for this example as being a victim of an aggressor signal.

In an exemplary embodiment, the first receive path 810 may include an antenna 812, a low noise amplifier (LNA) 814, an internal or interface LNA (iLNA) 815, a filter 830, a mixer 818, a divider 822, a voltage-controlled oscillator 824, a baseband filter (BBF) 826 and an analog-to-digital converter (ADC) 828. The divider 822 may, in this example, be a divide-by-m (DIV/M) divider capable of integer division or fractional division.

In an exemplary embodiment, the LNA 814 may be located external from a transceiver (Tx/Rx) on which the iLNA 815 may be located. In this example, a chip boundary 802 is indicated between the LNA 814 and iLNA 815 to denote the distinction between an LNA located off-chip (off the transceiver chip) from an iLNA located on the transceiver chip.

In an exemplary embodiment, the filter 830 may include one or more instances of an inductorless interference cancellation filter, with two instances 831 and 833 shown for illustrative purposes only. In an exemplary embodiment, a switch 835 may be implemented before the iLNA 815 and a switch 837 may be implemented after the iLNA 815 to switchably couple the instances 831 and 833 of the inductorless interference cancellation filter 830 to the first receive path 810. The switches 835 and 837 may be controlled by a signal from the controller 555 (FIG. 5) or the data processor 210 (FIG. 2). In an exemplary embodiment, the inductorless interference cancellation filter 831 may be operated prior to the iLNA 815 by closing the switch 835 and opening the switch 837. Similarly, the inductorless interference cancellation filter 833 may be operated after the iLNA 815 by closing the switch 837 and opening the switch 835. In some embodiments, it is possible that the inductorless interference cancellation filter 831 may be operated prior to the iLNA 815 and the inductorless interference cancellation filter 833 may be operated after the iLNA 815 by closing both switches 835 and 837 so that the spurious signals injected at the input of the iLNA 815 and injected at the output of the iLNA 815 can be attenuated. In other embodiments, both the switches 835 and 837 are coupled to a single instance (e.g., instance 831) of the inductorless interference cancellation filter, and selectively closing these switches determines whether that instance is operated before or after the iLNA 815.

In an exemplary embodiment, the second receive path 840 may include an antenna 842, a low noise amplifier (LNA) 844, an internal LNA (iLNA) 845, a filter 850, a mixer 848, a divider 852, a voltage-controlled oscillator 854, a baseband filter (BBF) 856 and an analog-to-digital converter (ADC) 858. The divider 852 may, in this example, be a divide-by-N(DIV/N) divider capable of integer division or fractional division.

In an exemplary embodiment, the LNA 844 may be located external from a transceiver (Tx/Rx) on which the iLNA 845 may be located. In this example, the chip boundary 802 is indicated between the LNA 844 and iLNA 845 to denote the distinction, as mentioned above.

In an exemplary embodiment, the filter 850 may include one or more instances of an inductorless interference cancellation filter, with two instances 851 and 853 shown for illustrative purposes only. In an exemplary embodiment, a switch 855 may be implemented before the iLNA 845 and a switch 857 may be implemented after the iLNA 845 to switchably couple the instances 851 and 853 of the inductorless interference cancellation filter 850 to the second receive path 840. The switches 855 and 857 may be controlled by a signal from the controller 555 (FIG. 5) or the data processor 210 (FIG. 2). In an exemplary embodiment, the inductorless interference cancellation filter 851 may be operated prior to the iLNA 845 by closing the switch 855 and opening the switch 857. Similarly, the inductorless interference cancellation filter 853 may be operated after the iLNA 845 by closing the switch 857 and opening the switch 855. In some embodiments, it is possible that the inductorless interference cancellation filter 851 may be operated prior to the iLNA 845 and the inductorless interference cancellation filter 853 may be implemented after the iLNA 845 by closing both switches 855 and 857 so that the spurious signals injected at the input of the iLNA 845 and injected at the output of the iLNA 845 can be attenuated. In other embodiments, both the switches 855 and 857 are coupled to a single instance (e.g., instance 851) of the inductorless interference cancellation filter, and selectively closing these switches determines whether that instance is operated before or after the iLNA 845.

In an exemplary embodiment, the third receive path 870 may include an antenna 872, a low noise amplifier (LNA) 874, an internal LNA (iLNA) 875, a filter 880, a mixer 878, a divider 882, a voltage-controlled oscillator 884, a baseband filter (BBF) 886 and an analog-to-digital converter (ADC) 888. The divider 882 may, in this example, be a divide-by-P (DIV/P) divider capable of integer division or fractional division.

In an exemplary embodiment, the LNA 874 may be located external from a transceiver (Tx/Rx) on which the internal LNA (iLNA) 875 may be located. In this example, the chip boundary 802 is indicated between the LNA 874 and iLNA 875 to denote the distinction, as mentioned above. The LNAs 814, 844, 874 and/or iLNAs 815, 845, 875 may be example implementations of the LNA 252 of FIGS. 2 and/or 614, 644 of FIG. 6. Elements in FIG. 8 may be similar in operation to corresponding elements in FIGS. 2 and 6, and will not be again described in detail.

In an exemplary embodiment, the filter 880 may include one or more instances of an inductorless interference cancellation filter, with two instances 881 and 883 shown for illustrative purposes only. In an exemplary embodiment, a switch 885 may be implemented before the iLNA 875 and a switch 887 may be implemented after the iLNA 875 to switchably couple the instances 881 and 883 of the inductorless interference cancellation filter 880 to the third receive path 870. The switches 885 and 887 may be controlled by a signal from the controller 555 (FIG. 5) or the data processor 210 (FIG. 2). In an exemplary embodiment, the inductorless interference cancellation filter 881 may be operated prior to the iLNA 875 by closing the switch 885 and opening the switch 887. Similarly, the inductorless interference cancellation filter 883 may be operated after the iLNA 875 by closing the switch 887 and opening the switch 885. In some embodiments, it is possible that the inductorless interference cancellation filter 881 may be operated prior to the iLNA 875 and the inductorless interference cancellation filter 883 may be operated after the iLNA 875 by closing both switches 885 and 887 so that the spurious signals injected at the input of the iLNA 875 and injected at the output of the iLNA 875 can be attenuated. In other embodiments, both the switches 885 and 887 are coupled to a single instance (e.g., instance 881) of the inductorless interference cancellation filter, and selectively closing these switches determines whether that instance is operated before or after the iLNA 875.

Although described in FIG. 8 as having three receive paths 810, 840 and 870, it should be understood that the receiver circuit 800 may include more of fewer receive paths. Further, additional inductorless interference cancellation filters, or instances thereof, may be implemented. In some embodiments, a filter instance may be disposed at a different location than illustrated along one or more of the receive paths. For example, an instance of the inductorless interference cancellation filter may be persistently or selectively coupled to the receive path between the mixer and the BBF. In some such embodiments, instead of being configured to filter a victim or aggressor signal, the inductorless interference cancellation filter coupled to the receive path between the mixer and the BBF is configurable to filter a signal having a beat frequency which is the difference between the frequency of harmonics in two receive paths.

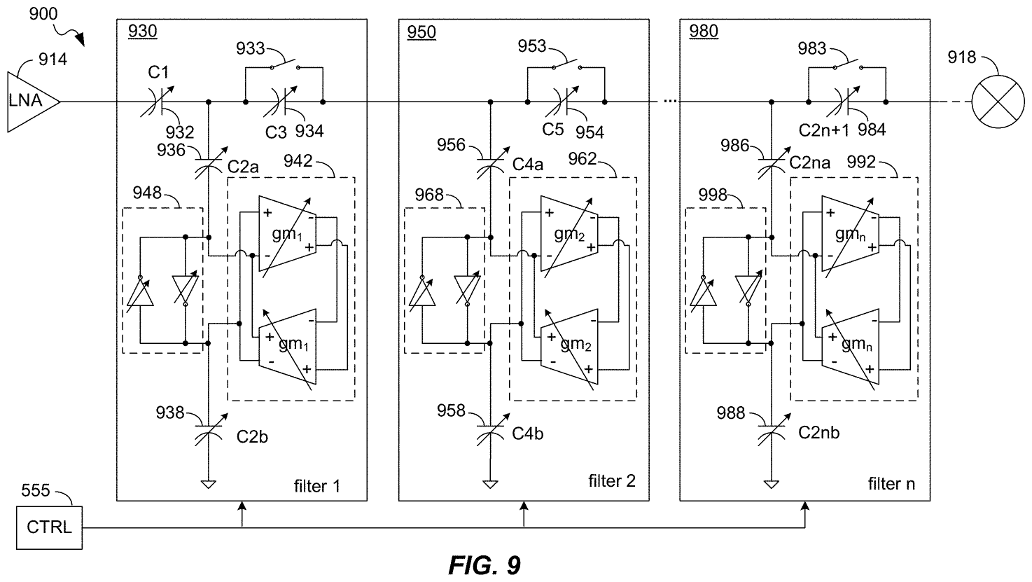

FIG. 9 is a schematic diagram 900 showing an exemplary embodiment of an inductorless interference cancellation filter arrangement. The diagram 900 shows an LNA 914, a mixer 918 and an example of a filter arrangement that includes three instances of an inductorless interference cancellation filter 930, 950, and 980. However, more (e.g., four, five, six, or more) or fewer (e.g., one or two) instances of the inductorless interference cancellation filter may be implemented. For example, a number of filter instances in a receive path may be equivalent to a number of carriers or bands used in other receive paths or in all of the potentially interfering receive paths. The LNA 914 and the mixer 918 are similar to the LNAs and mixers described in FIG. 3 and FIG. 4. The inductorless interference cancellation filters 930, 950, and 980 are similar to the inductorless interference cancellation filter 550 described in FIG. 5, and will not be described again in detail.

In an exemplary embodiment, an inductorless interference cancellation filter 930 may comprise adjustable capacitances 932, 934, 936 and 938, a switch 933 located around the adjustable capacitance 934; an active gyrator circuit 942 and a Q-boost circuit 948. Details of the active gyrator circuit 942 and a Q-boost circuit 948 were described in FIG. 5 and will not be repeated.

In an exemplary embodiment, an inductorless interference cancellation filter 950 may comprise adjustable capacitances 954, 956 and 958, a switch 953 located around the adjustable capacitance 954; an active gyrator circuit 962 and a Q-boost circuit 968. Details of the active gyrator circuit 962 and a Q-boost circuit 968 were described in FIG. 5 and will not be repeated. The inductorless interference cancellation filter 950 omits an adjustable capacitance similar to the adjustable capacitance 932 (C1 of filter instance 930) because such a capacitance may not be needed when two or more inductorless interference cancellation filter instances are implemented in series. In other embodiments, this adjustable capacitance is included.

In an exemplary embodiment, an inductorless interference cancellation filter 980 may comprise adjustable capacitances 984, 986 and 988, a switch 983 located around the adjustable capacitance 984; an active gyrator circuit 992 and a Q-boost circuit 998. Details of the active gyrator circuit 992 and a Q-boost circuit 998 were described in FIG. 5 and will not be repeated.

The controller 555 may be used to determine the frequency or frequencies to which the instances 930, 950 and 980 of the inductorless interference cancellation filter may be set. Separate control signals from the controller 555, separate control paths, separate bits of a control signal from the controller 555, or other such means may allow for each of the instances 930, 950, and 980 (and any other instances in the inductorless interference cancellation filter arrangement) to be independently configured/re-configured.

In an exemplary embodiment, the three instances 930, 950 and 980 of the inductorless interference cancellation filter may be set to different frequencies, may be set to the same frequency, or two of the instances of the inductorless interference cancellation filters may be set to frequencies that are close so as to extend the frequency range of a stop band.

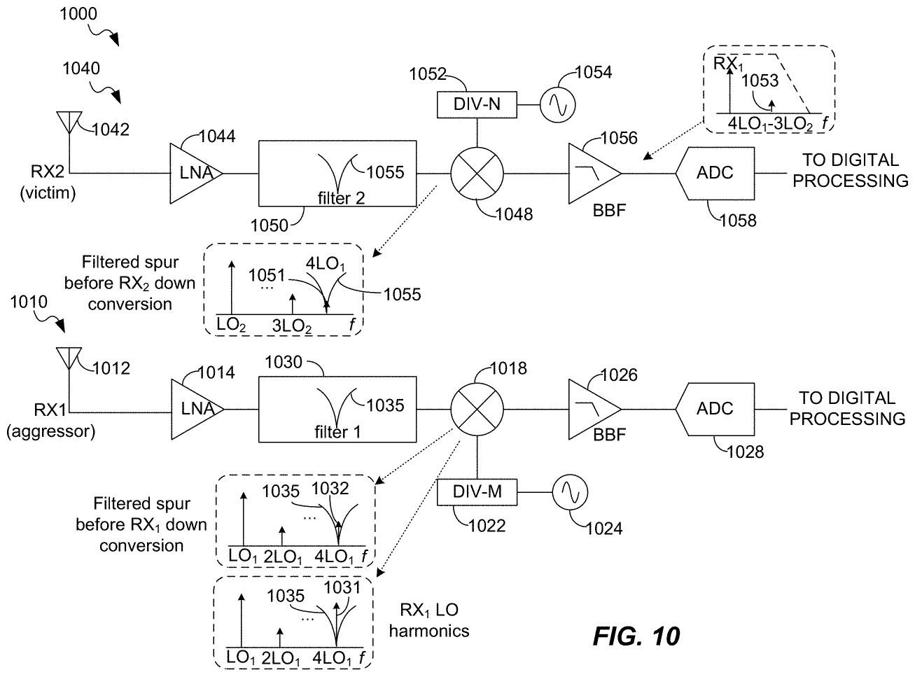

FIG. 10 is a schematic diagram of a receiver circuit 1000 showing an exemplary embodiment of an implementation of an inductorless interference cancellation filter. The exemplary embodiment of FIG. 10 shows a case where two carrier-aggregated communication signals appear in two receive paths.

In an exemplary embodiment, the receiver circuit 1000 includes a first receive path 1010 and a second receive path 1040. In an exemplary embodiment, the first receive path 1010 may be referred to as RX1 and may be considered for this example as generating an aggressor signal. In an exemplary embodiment, the second receive path 1040 may be referred to as RX2 and may be considered for this example as being a victim of an aggressor signal. Although described in FIG. 10 as having two receive paths 1010 and 1040, it should be understood that the receiver circuit 1000 may include more of fewer receive paths.

In an exemplary embodiment, the first receive path 1010 may include an antenna 1012, a low noise amplifier (LNA) 1014, a filter 1030, a mixer 1018, a divider 1022, a voltage-controlled oscillator 1024, a baseband filter (BBF) 1026 and an analog-to-digital converter (ADC) 1028. The divider 1022 may, in this example, be a divide-by-M (DIV/M) divider capable of integer division or fractional division.

In an exemplary embodiment, the second receive path 1040 may include an antenna 1042, a low noise amplifier (LNA) 1044, a filter 1050, a mixer 1048, a divider 1052, a voltage-controlled oscillator 1054, a baseband filter (BBF) 1056 and an analog-to-digital converter (ADC) 1058. The divider 1052 may, in this example, be a divide-by-N(DIV/N) divider capable of integer division or fractional division. Elements in FIG. 10 may be similar in operation to corresponding elements in FIGS. 2 and 6 and will not be again described in detail.

In an exemplary embodiment, a signal in one of the first receive path 1010 or the second receive path 1040 may interfere with the reception of a communication signal in a receive band of the other of the first receive path 1010 or the second receive path 1040.

In an exemplary embodiment, each of the first receive path 1010 and the second receive path 1040 may implement one or more instances of an inductorless interference cancellation filter in accordance with an exemplary embodiment of the disclosure.

For example, the first receive path 1010 may implement an inductorless interference cancellation filter 1030 and the second receive path 1040 may implement an inductorless interference cancellation filter 1050.

In the example shown in FIG. 10, the receive path 1010 may be operating in the B7 band, the LO frequency used by the mixer 1018 may be 2688 MHz, and a 4th harmonic of the LO frequency may appear at a frequency of 10752 MHz, shown as signal 1031. This signal 1031 may appear as an aggressor spurious signal to the second receive path 1040. The response of the filter 1030 is shown using reference numeral 1035. As illustrated, filter 1030 may be configured with a notch at approximately the same frequency as the 4^{th} harmonic of the LO₁ frequency so as to filter the signal 1031.

In the example shown in FIG. 10, the second receive path 1040 may be operating in the n78 band, the LO frequency used by the mixer 1048 may be 3583 MHz, and a 3^{rd} harmonic of the LO frequency may appear at a frequency of 10747 MHz. The response of the filter 1050 is shown using reference numeral 1055. As illustrated, filter 1050 may be configured with a notch at approximately the same frequency as the 4^{th} harmonic of the LO₁ frequency so as to filter a signal at this frequency. Such filtering may attenuate or eliminate a signal 1053 having a beat frequency that is the difference between the 4^{th} harmonic of the LO₁ frequency and the 3^{rd} harmonic of the LO₂ frequency. Attenuating or reducing the signal 1053 may be beneficial because such signal may be passed by the BBF 1056 for further processing.

The inductorless interference cancellation filter 1030 and the inductorless interference cancellation filter 1050 may be implemented before signal downconversion to attenuate spurious LO signal energy. For example, the inductorless interference cancellation filter 1030 in the first receive path 1010 may attenuate aggressor spurious signal energy, that is LO harmonics such as signal 1031 generated by the LO-RF dowconversion in mixer 1018, so that the signal energy 1031 is attenuated to appear as signal energy 1032. In the example, the inductorless interference cancellation filter 1050 in the second receive path 1040 may also be implemented to attenuate spurious signal energy that may be coupled from the mixer 1018 to the mixer 1048, so that this signal energy is also attenuated, shown using reference numeral 1051.

In an exemplary embodiment, based on the band combinations and channel frequencies of each receive path, the aggressor and victim frequencies can be derived, and such information may be stored in the controller 555 (FIG. 5) or data processor 210 or memory 298 (FIG. 2), for example, in the form of a look up table. The frequency information may be extracted and used to determine the aggressor and victim frequencies based on the band combinations. For example, as mentioned above, the receive path 1010 may be operating in the B7 band, the LO frequency used by the mixer 1018 may be 2688 MHz, and a 4^{th} harmonic of the LO frequency may appear at a frequency of 10752 MHz; and the second receive path 1040 may be operating in the n78 band, the LO frequency used by the mixer 1048 may be 3583 MHz, and a 3^{rd} harmonic of the LO frequency may appear at a frequency of 10747 MHz. The aggressor frequency of 10752 MHz and the victim frequency of 10747 MHz may be so determined and the inductorless interference cancellation filter 1030 and the inductorless interference cancellation filter 1050 may be configured as described above to attenuate undesired signal energy.

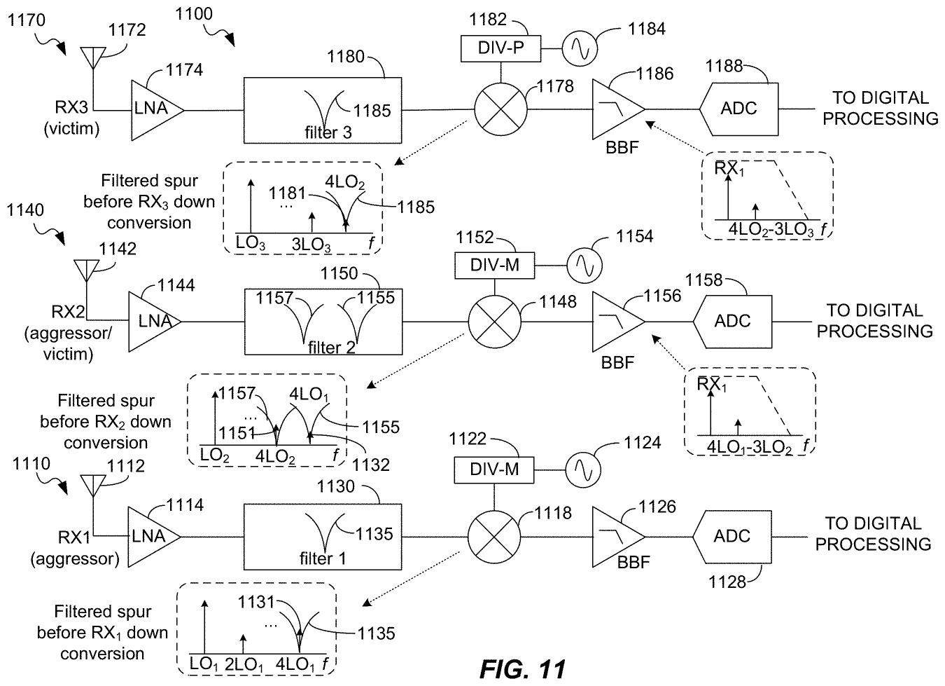

FIG. 11 is a schematic diagram of a receiver circuit 1100 showing an exemplary embodiment of an implementation of an inductorless interference cancellation filter. The exemplary embodiment of FIG. 11 shows a case where three carrier-aggregated communication signals appear in three receive paths.

In an exemplary embodiment, the receiver circuit 1100 includes a first receive path 1110, a second receive path 1140, and a third receive path 1070. In an exemplary embodiment, the first receive path 1110 may be referred to as RX1 and may be considered for this example as generating an aggressor signal. In an exemplary embodiment, the second receive path 1140 may be referred to as RX2 and may be considered for this example as generating an aggressor signal and also being a victim of another aggressor signal. In an exemplary embodiment, the third receive path 1170 may be referred to as RX3 and may be considered for this example a victim of an aggressor signal. Although described in FIG. 11 as having three receive paths 1110, 1140 and 1170, it should be understood that the receiver circuit 1100 may include more of fewer receive paths.

In an exemplary embodiment, the first receive path 1110 may include an antenna 1112, a low noise amplifier (LNA) 1114, a filter 1130, a mixer 1118, a divider 1122, a voltage-controlled oscillator 1124, a baseband filter (BBF) 1126 and an analog-to-digital converter (ADC) 1128. The divider 1122 may, in this example, be a divide-by-M (DIV/M) divider capable of integer division or fractional division.

In an exemplary embodiment, the second receive path 1140 may include an antenna 1142, a low noise amplifier (LNA) 1144, a filter 1150, a mixer 1148, a divider 1152, a voltage-controlled oscillator 1154, a baseband filter (BBF) 1156 and an analog-to-digital converter (ADC) 1158. The divider 1152 may, in this example, be a divide-by-N(DIV/N) divider capable of integer division or fractional division.

In an exemplary embodiment, the third receive path 1170 may include an antenna 1172, a low noise amplifier (LNA) 1174, a filter 1180, a mixer 1178, a divider 1182, a voltage-controlled oscillator 1184, a baseband filter (BBF) 1186 and an analog-to-digital converter (ADC) 1188. The divider 1182 may, in this example, be a divide-by-P (DIV/P) divider capable of integer division or fractional division. Elements in FIG. 11 may be similar in operation to corresponding elements in FIGS. 2 and 6 and will not be again described in detail.

In an exemplary embodiment, a signal in one of the first receive path 1110, the second receive path 1140, or the third receive path 1170 may interfere with the reception of a communication signal in a receive band of another of the first receive path 1110, the second receive path 1140 or the third receive path 1170.

In an exemplary embodiment, each of the first receive path 1110, the second receive path 1140, and the third receive path 1170 may implement one or more instances of an inductorless interference cancellation filter in accordance with an exemplary embodiment of the disclosure.

For example, the first receive path 1110 may implement an inductorless interference cancellation filter 1130, the second receive path 1140 may implement an inductorless interference cancellation filter 1150, and the third receive path 1170 may implement an inductorless interference cancellation filter 1180.

In the example shown in FIG. 11, the first receive path 1110 may be operating in the B2 band, the LO frequency used by the mixer 1118 may be 1985 MHz, and a 4th harmonic of the LO frequency may appear at a frequency of 7940 MHz, shown as signal 1131. This signal 1131 may appear as an aggressor spurious signal to the second receive path 1140. The response of the filter 1130 is shown using reference numeral 1135.

In the example shown in FIG. 11, the second receive path 1140 may be operating in the B7 band, the LO frequency used by the mixer 1148 may be 2646 MHz. An LO of 2646 MHz results in a 3^{rd} harmonic that may appear at a frequency of 7938 MHz and a 4^{th} harmonic that may appear at a frequency of 10584 MHz. In this example, the second receive path 1140 may suffer desensitization (i.e., be a victim) from the energy of the signal 1131 (i.e., the 4^{th} harmonic of the LO of the first receive path 1110 at 7940 MHz), and may also create an aggressor signal to the third receive path (n78 band in this example), because the LO frequency of 2646 MHz translates to a 4^{th} harmonic at 10584 MHz. The response of the filter 1150 is shown using reference numerals 1155 and 1157.

In the example shown in FIG. 11, the third receive path 1170 may be operating in the n78 band, the LO frequency used by the mixer 1178 may be 3527 MHz. An LO of 3527 MHz results in a 3^{rd} harmonic that may appear at a frequency of 10581 MHz. In this example, the 4^{th} harmonic of the LO of the second receive path 1140 at 10584 MHz becomes an aggressor to desensitize the third receive path 1170 because the 3^{rd} harmonic of the LO of the third receive path 1170 appears at a frequency of 10581 MHz.

The inductorless interference cancellation filter 1130, the inductorless interference cancellation filter 1150 and the inductorless interference cancellation filter 1180 may be implemented before signal downconversion to attenuate spurious LO signal energy.

For example, the inductorless interference cancellation filter 1130 in the first receive path 1110 may attenuate aggressor spurious signal energy, that is LO harmonics such as signal 1131 generated by the LO-RF dowconversion in mixer 1118, so that the signal energy 1131 is attenuated to appear as signal energy 1132 in the second receive path 1140.

In this example, the inductorless interference cancellation filter 1150 in the second receive path 1140 may be implemented with two filter responses 1155 and 1157. The response 1155 may be implemented to attenuate the signal 1132 from the first receive path 1110. The response 1157 may be implemented to attenuate spurious signal energy that may be coupled from the mixer 1148, so that this signal energy is also attenuated, shown using reference numeral 1151.

In this example, the inductorless interference cancellation filter 1180 in the third receive path 1170 may be implemented with filter response 1185. The response 1185 may be implemented to attenuate spurious signal energy that may be coupled from second receive path 1140, shown using reference numeral 1181.

In exemplary embodiments, inductorless interference cancellation filters may be implemented on both aggressor and victim receive paths, may be implemented on only an aggressor receive path, or may be implemented only on a victim receive path.

In certain of the examples described above, each receive path is illustrated as being coupled to a respective antenna. In other embodiments, however, multiple receive paths (where one or more of the multiple receive paths include an inductorless interference cancellation filter) may be coupled to a common antenna.

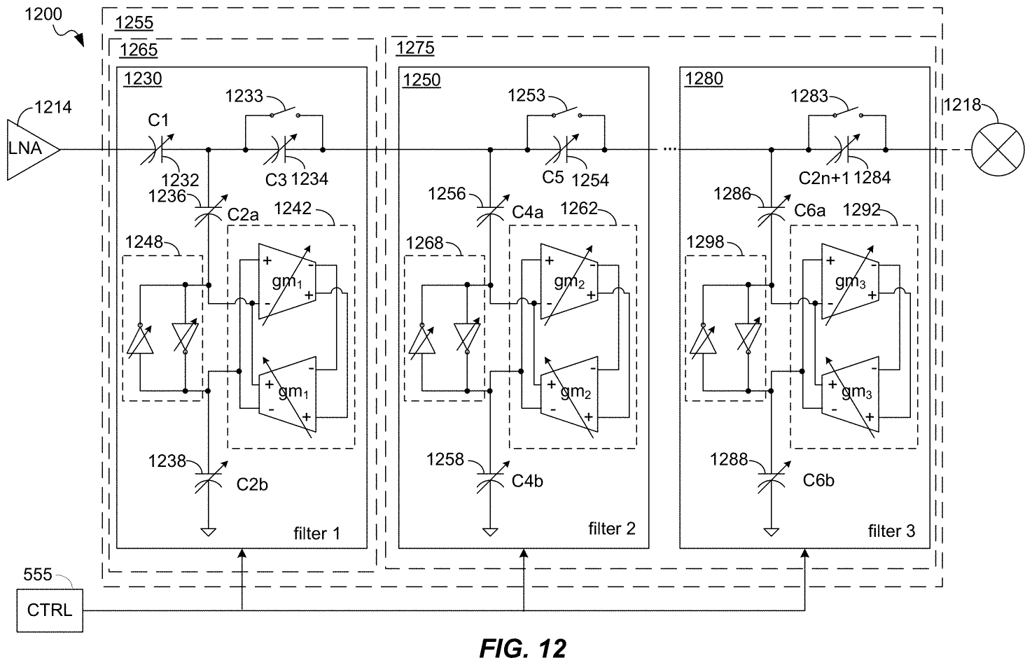

FIG. 12 is a schematic diagram 1200 showing an exemplary embodiment of an inductorless interference cancellation filter arrangement. The diagram 1200 shows an LNA 1214, a mixer 118 and an example of a filter arrangement that includes three instances of an inductorless interference cancellation filter 1230, 1250, and 1280. However, more (e.g., four, five, six, or more) or fewer (e.g., one or two) instances of the inductorless interference cancellation filter may be implemented. For example, a number of filter instances in a receive path may be equivalent to a number of carriers or bands used in other receive paths or in all of the potentially interfering receive paths. The LNA 1214 and the mixer 1218 are similar to the LNAs and mixers described in FIG. 3 and FIG. 4. The inductorless interference cancellation filters 1230, 1250, and 1280 are similar to the inductorless interference cancellation filters 930, 950 and 980 described in FIG. 9.

In an exemplary embodiment, an inductorless interference cancellation filter 1230 may comprise adjustable capacitances 1232, 1234, 1236 and 1238, a switch 1233 located around the adjustable capacitance 1234; an active gyrator circuit 1242 and a Q-boost circuit 1248. Details of the active gyrator circuit 1242 and a Q-boost circuit 1248 were described in FIG. 5 and will not be repeated.

In an exemplary embodiment, an inductorless interference cancellation filter 1250 may comprise adjustable capacitances 1254, 1256 and 1258, a switch 1253 located around the adjustable capacitance 1254; an active gyrator circuit 1262 and a Q-boost circuit 1268. Details of the active gyrator circuit 1262 and a Q-boost circuit 1268 were described in FIG. 5 and will not be repeated. The inductorless interference cancellation filter 1250 omits an adjustable capacitance similar to the adjustable capacitance 1232 because such a capacitance may not be needed when two or more inductorless interference cancellation filters are implemented in series. In other embodiments, this adjustable capacitance is included.

In an exemplary embodiment, an inductorless interference cancellation filter 1280 may comprise adjustable capacitances 1284, 1286 and 1288, a switch 1283 located around the adjustable capacitance 1284; an active gyrator circuit 1292 and a Q-boost circuit 1298. Details of the active gyrator circuit 1292 and a Q-boost circuit 1298 were described in FIG. 5 and will not be repeated.

In an exemplary embodiment, the three instances of the inductorless interference cancellation filters may be set to different frequencies, may be set to the same frequency, or two or three of the instances of the inductorless interference cancellation filters may be set to frequencies that are close so as to extend the frequency range of a stop band.

For example, if the capacitances 1236 (C2a), 1256 (C4a) and 1286 (C6a) are set to the same value, if the capacitances 1238 (C2b), 1258 (C4b) and 1288 (C6b) are set to the same value, and if the gain of the active gyrator circuits 1242, 1262 and 1292 are set to the same value, then the three instances of the inductorless interference cancellation filters 1230, 1250 and 1280 will be set to the same notch frequency and will appear as a single filter 1255 at a single notch frequency.

In another example, if the capacitance 1236 (C2a) is set to a first value and the capacitances 1256 (C4a) and 1286 (C6a) are set to a second value; and if the capacitance 1238 (C2b) is set to a different first value and the capacitances 1258 (C4b) and 1288 (C6b) are set to a different second value, and if the active gyrator circuit 1242 is set to a first gain, and the active gyrator circuits 1262 and 1292 are set to a different gain, then the first instance of the inductorless interference cancellation filter 1230 will be set to a first frequency and appear as a first inductorless interference cancellation filter instance 1265; and the second and third instances of the inductorless interference cancellation filter 1250 and 1280 will both be set to a second frequency and appear as a second inductorless interference cancellation filter instance 1275, such that an equivalent circuit would appear as a dual notch filter at a first notch frequency and a second notch frequency, where the second notch frequency may provide more attenuation than the first notch frequency.

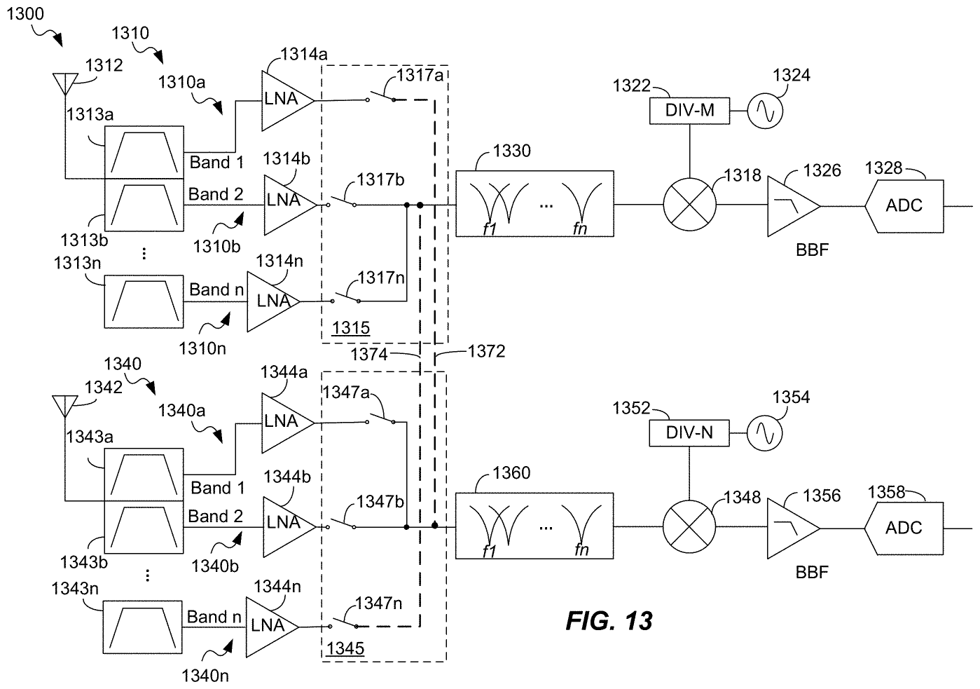

FIG. 13 is a schematic diagram of a receiver circuit 1300 showing an exemplary embodiment of an implementation of an inductorless interference cancellation filter. In an exemplary embodiment, the receiver circuit 1300 includes a first receiver 1310. In an exemplary embodiment, the first receiver 1310 may include an antenna 1312 coupled to one or more bandpass filters 1313. In this exemplary embodiment, the antenna 1312 may be coupled to bandpass filters 1313a, 1313b and 1313n. Each bandpass filter 1313 corresponds to a receive path 1310a, 1310b and 1310n. Any number of antennas, bandpass filters and receive paths may be implemented.

In an exemplary embodiment, the receive path 1310a includes a bandpass filter 1313a, an LNA 1314a and a switch 1317a; the receive path 1310b includes a bandpass filter 1313b, an LNA 1314b and a switch 1317b, and the receive path 1310n includes a bandpass filter 1313n, an LNA 1314n and a switch 1317n. The switches 1317a, 1317b and 1317n may form a switch network 1315.

The switch network 1315 may be coupled to an inductorless interference cancellation filter 1330, which is similar to the other inductorless interference cancellation filters described herein. The inductorless interference cancellation filter 1330 may be coupled to a mixer 1318, a divider 1322, a voltage-controlled oscillator 1324, a baseband filter 1326 and an ADC 1328, as described above.

In an exemplary embodiment, the receiver circuit 1300 includes a second receiver 1340. In an exemplary embodiment, the second receiver 1340 may include an antenna 1342 coupled to one or more bandpass filters 1343. In this exemplary embodiment, the antenna 1342 may be coupled to bandpass filters 1343a, 1343b and 1343n. Each bandpass filter 1343 corresponds to a receive path 1340a, 1340b and 1340n. Any number of antennas, bandpass filters and receive paths may be implemented.

In an exemplary embodiment, the receive path 1340a includes a bandpass filter 1343a, an LNA 1344a and a switch 1347a; the receive path 1340b includes a bandpass filter 1343b, an LNA 1344b and a switch 1347b, and the receive path 1340n includes a bandpass filter 1343n, an LNA 1344n and a switch 1347n. The switches 1347a, 1347b and 1347n may form a switch network 1345.

The switch network 1345 may be coupled to an inductorless interference cancellation filter 1360, which is similar to the other inductorless interference cancellation filters described herein. The inductorless interference cancellation filter 1360 may be coupled to a mixer 1348, a divider 1352, a voltage-controlled oscillator 1354, a baseband filter 1356 and an ADC 1358, as described above.

In an exemplary embodiment, elements of the first receiver 1310 may be coupled to elements of the second receiver 1340, resulting in what may be referred to as cross-routing.

For example, the bandpass filter 1313a and LNA 1314a for Band 1 in the receiver 1310a may be coupled to the inductorless interference cancellation filter 1360 over routing 1372; and the bandpass filter 1343n and LNA 1344n for Band n in the receiver 1340n may be coupled to the inductorless interference cancellation filter 1330 over routing 1374. The connections 1372 and 1374 illustrate cross-routing, on which the LO harmonics or spurious signals can couple between the first receiver 1310 and the second receiver 1340. In an exemplary embodiment, the inductorless interference cancellation filter 1330 and the inductorless interference cancellation filter 1360 may be implemented as described herein to mitigate the effect of signal coupling between the first receiver 1310 and the second receiver 1340 over connections 1372 and 1374.

In other embodiments, no cross-routing between the receivers 1310, 1340 is implemented. For example, the switch 1317a may be coupled to the inductorless interference cancellation filter 1330 and the switch 1347n may be coupled to the inductorless interference cancellation filter 1360. In such embodiments, LO harmonics or spurious signals coupling between the receivers 1310, 1340 may still be possible, and the inductorless interference cancellation filter 1330 and the inductorless interference cancellation filter 1360 may be implemented as described herein to mitigate the effect of signal coupling between the first receiver 1310 and the second receiver 1340.

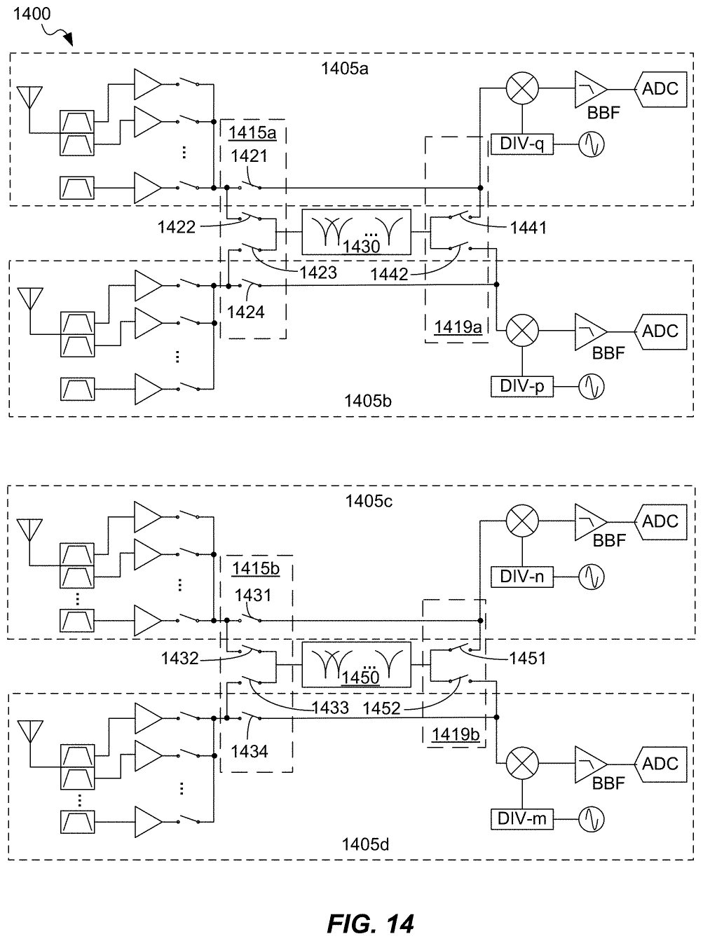

FIG. 14 is a schematic diagram of a receiver circuit 1400 showing an exemplary embodiment of an implementation of an inductorless interference cancellation filter. In an exemplary embodiment, the receiver circuit 1400 includes four exemplary instances of receivers that are similar to the receivers 1310, 1340 of FIG. 13, except that in FIG. 14 an inductorless interference cancellation filter is shared between two receivers. In FIG. 14, the receivers are labeled 1405a, 1405b, 1405c and 1405d. The receiver circuit 1400 also includes an inductorless interference cancellation filter 1430 associated with the receiver circuits 1405a and 1405b; and an inductorless interference cancellation filter 1450 associated with the receiver circuits 1405c and 1405d. Any number of receivers may be implemented, and any number of receivers may share an inductorless interference cancellation filter.

In an exemplary embodiment, the inductorless interference cancellation filter 1430 may be coupled to the receivers 1405a and 1405b through a switch network 1415a and a switch network 1419a. In an exemplary embodiment, the inductorless interference cancellation filter 1450 may be coupled to the receivers 1405c and 1405d through a switch network 1415b and a switch network 1419b.

In an exemplary embodiment, the switch network 1415a may comprise switches 1421, 1422, 1423 and 1424 and the switch network 1419a may comprise switches 1441 and 1442. In an exemplary embodiment, the switch network 1415b may comprise switches 1431, 1432, 1433 and 1434 and the switch network 1419b may comprise switches 1451 and 1452. The switches in the switch networks 1415a, 1415b, 1419a and 1419b may be controlled by signals from the controller 555 (FIG. 5), or from signals generated by the data processor 210 (FIG. 2).

The switches in the switch networks 1415a and 1419a may be selectively controlled to couple or uncouple the inductorless interference cancellation filter 1430 from the receivers 1405a and 1405b. Similarly, the switches in the switch networks 1415b and 1419b may be selectively controlled to couple or uncouple the inductorless interference cancellation filter 1450 from the receivers 1405c and 1405d.

For example, if switch 1421 is closed (and switch 1422 is open), then the inductorless interference cancellation filter 1430 is bypassed with respect to receiver 1405a. If the switch 1421 is open (and the switches 1422 and 1441 are closed), then the inductorless interference cancellation filter 1430 is included in the receiver 1405a.

Similarly, if the switch 1424 is closed (and switch 1423 is open), then the inductorless interference cancellation filter 1430 is bypassed with respect to receiver 1405b. If the switch 1424 is open (and the switches 1423 and 1442 are closed), then the inductorless interference cancellation filter 1430 is included in the receiver 1405b.

If the switch 1431 is closed (and switch 1432 is open), then the inductorless interference cancellation filter 1450 is bypassed with respect to receiver 1405c. If the switch 1431 is open (and the switches 1432 and 1451 are closed), then the inductorless interference cancellation filter 1450 is included in the receiver 1405c.

Similarly, if the switch 1434 is closed (and switch 1433 is open), then the inductorless interference cancellation filter 1450 is bypassed with respect to receiver 1405d. If the switch 1434 is open (and the switches 1433 and 1452 are closed), then the inductorless interference cancellation filter 1450 is included in the receiver 1405d.

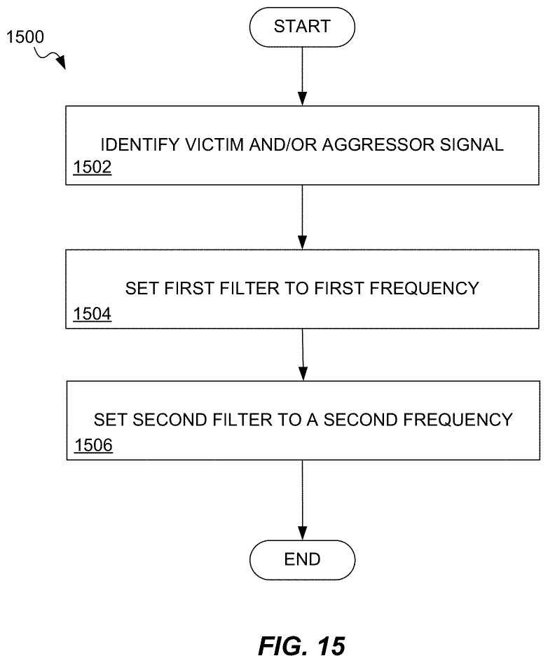

FIG. 15 is a flow chart 1500 describing an example of the operation of an inductorless interference cancellation filter. The blocks in the method 1500 can be performed in or out of the order shown, and in some embodiments, can be performed at least in part in parallel.

In block 1502, a victim and/or an aggressor signal is identified. For example, as described above in FIG. 10, the receive path 1010 may be operating in the B7 band, the LO frequency used by the mixer 1018 may be 2688 MHz, and a 4^{th} harmonic of the LO frequency may appear at a frequency of 10752 MHz, shown as signal 1031. This signal 1031 may appear as an aggressor spurious signal to the second receive path 1040. The second receive path 1040 may have an operating frequency that may fall victim to the aggressor signal.

In block 1504, a first instance of an inductorless interference cancellation filter is set to a first frequency. For example, an instance of the inductorless interference cancellation filter described herein may be set to a first frequency to create a notch response at the first (or selected) frequency.

In block 1506, a second instance of an inductorless interference cancellation filter is set to a second frequency. For example, an instance of the inductorless interference cancellation filter described herein may be set to a second frequency to create a notch response at the second (or selected) frequency. The first and second instances may be in the same receive path or in different receive paths. Additional instances may be included in each receive path or in other receive paths.

The first frequency may be different than the second frequency, in which case the inductorless interference cancellation filter may establish two different notch responses at two different selected frequencies. For example, the filter 1150 in FIG. 11 is set to exhibit at least two responses 1155 and 1157. When filter instances are implemented in separate receive chains, an instance in the filter 1130 may be set to exhibit the response 1135 and an instance in the filter 1150 may be set to exhibit the response 1155.

The first frequency may be the same as the second frequency, in which case the inductorless interference cancellation filter may establish a notch response at a selected frequency, where the notch response at the selected frequency provides greater signal attenuation at the selected frequency than if only a single instance of the inductorless interference cancellation filter were set to the selected frequency. In some embodiments, the filter 1130 and/or the filter 1180 may include multiple instances which are set to exhibit the same response (e.g., 1135 for filter 1130 or 1185 for filter 1180).

The first frequency may be close to the second frequency, such that a stop band may be created that spans the first frequency and the second frequency, thus extending the frequency range of the stop band. The inductorless interference cancellation filter can also be set to additional frequencies that may be the same or different than the first frequency and the second frequency.

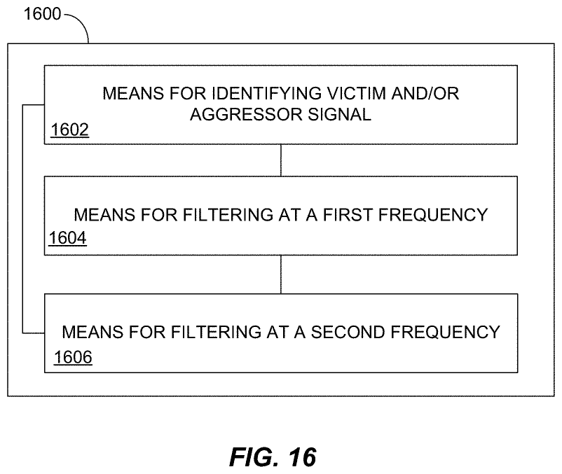

FIG. 16 is a functional block diagram of an apparatus 1600 for filtering a received communication signal. The apparatus 1600 comprises means 1602 for identifying a victim and/or an aggressor signal. In certain embodiments, the means 1602 for identifying a victim and/or an aggressor frequency can be configured to perform one or more of the functions described in operation block 1502 of method 1500 (FIG. 15). In an exemplary embodiment, the means 1502 for identifying a victim and/or an aggressor frequency may comprise the data processor 210, the processor 296, the memory 298, and/or the controller 555. For example, one or more of these elements (alone or in combination) may be configured to identify an aggressor signal, such as signal 1031 of FIG. 10, and/or identify a victim (e.g., the 3^{rd} harmonic of the LO₂ frequency in the example of FIG. 10) having an operating frequency susceptible to the aggressor signal.

The apparatus 1600 comprises means 1604 for filtering at a first frequency. In certain embodiments, the means 1604 for filtering at a first frequency can be configured to perform one or more of the functions described in operation block 1504 of method 1500 (FIG. 15). In an exemplary embodiment, the means 1504 for filtering at a first frequency may comprise an instance of the inductorless interference cancellation filter described herein being set to a first frequency to create a notch response at the first (or selected) frequency.

The apparatus 1600 also comprises means 1606 for filtering at a second frequency. The means 1606 for filtering at a second frequency can be configured to perform one or more of the functions described in operation block 1506 of method 1500 (FIG. 15). In an exemplary embodiment, the means 1606 for filtering at a second frequency may comprise an instance of the inductorless interference cancellation filter described herein being set to a second frequency to create a notch response at the second (or selected) frequency. The apparatus 1600 can also be set to additional frequencies that may be the same or different than the first frequency and the second frequency.

Exemplary embodiments of an inductorless interference cancellation filter may improve receiver signal-to-noise ratio (SNR) by filtering signals in one or more receive paths, for example prior to signal downconversion.

Exemplary embodiments of an inductorless interference cancellation filter may attenuate spurious signal(s) that occur in a receive band, and may be used to increase signal throughput in a 5G ENDC (i.e., 4G+5G carrier-aggregation) communication system in some configurations.

Exemplary embodiments of an inductorless interference cancellation filter may be implemented with minimal consumption of circuit area in some embodiments. For example, the area consumed by the active gyrator circuit may be significantly smaller than an on-chip coil inductor or off-chip inductors. Using an active gyrator circuit instead of a passive-inductor filter may additionally reduce on-chip electromotive coupling among receivers and receive paths and improve signal isolation.

Exemplary embodiments of an inductorless interference cancellation filter may allow for the elimination of band-specific filters due to the reconfigurable filter operation.

Exemplary embodiments of an inductorless interference cancellation filter reduce the need for additional local oscillator division ratio options, thereby reducing the total number of LOs and/or VCOs in the transceiver.

Exemplary embodiments of an inductorless interference cancellation filter may consume less power than other filtering methodologies, such as harmonic rejection mixers and digital spurious signal cancellation solutions, and/or may reduce complexity of circuit design.

The circuit architecture described herein described herein may be implemented on one or more ICs, analog ICs, RFICs, mixed-signal ICs, ASICs, printed circuit boards (PCBs), electronic devices, etc. The circuit architecture described herein may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), heterojunction bipolar transistors (HBTs), high electron mobility transistors (HEMTs), silicon-on-insulator (SOI), etc.

Example embodiments are described in the following numbered clauses.

1. A programmable filter, comprising:

a first programmable filter instance comprising a first adjustable active inductance capacitively coupled to a signal receive path, the capacitive coupling comprising at least one adjustable capacitance, the adjustable active inductance and the at least one adjustable capacitance configurable to provide a filter response at a first selected frequency; and

a second programmable filter instance comprising a second adjustable active inductance capacitively coupled to the signal receive path, the capacitive coupling comprising at least one adjustable capacitance, the second adjustable active inductance and the at least one adjustable capacitance configurable to provide a filter response at a second selected frequency.

2. The programmable filter of clause 1, wherein the first selected frequency is different than the second selected frequency.

3, The programmable filter of clause 1, wherein the first selected frequency is the same as the second selected frequency.

4. The programmable filter of clause 3, wherein the first selected frequency being the same as the second selected frequency increases attenuation at the first and second selected frequency.

5. The programmable filter of clause 1, wherein the first selected frequency and the second selected frequency are sufficiently close to create a communication signal stop band.

6. The programmable filter of any of clauses 1 through 5, wherein the programmable filter is implemented in at least one aggressor signal receive path, at least one victim signal receive path or in both an aggressor signal receive path and a victim signal path.

7. The programmable filter of any of clauses 1 through 6, further comprising a switch network configured to selectively couple the programmable filter to a receive path one of before or after a low noise amplifier (LNA).

8. The programmable filter of any of clauses 1 through 7, further comprising a switch network configured to selectively couple the programmable filter to one or more receive paths.

9. The programmable filter of any of clauses 1 through 8, wherein the programmable filter is coupled between an output of a low noise amplifier (LNA) and an input of a mixer.

10. The programmable filter of clause 9, wherein the LNA, the programmable filter, and the mixer are implemented on a chip, and wherein a signal path between an input of the chip and an output of the programmable filter is inductorless.

11. The programmable filter of any of clauses 1 through 10, wherein the programmable filter includes three (3) or more programmable filter instances.

12. The programmable filter of any of clauses 1 through 10, wherein the programmable filter includes five (5) or more programmable filter instances.

13. The programmable filter of any of clauses 1 through 12, wherein the programmable filter is disposed in a receive path configured to implement E-UTRAN New Radio Dual Connectivity.

14 The programmable filter of any of clauses 1 through 13, wherein the adjustable active inductance of the first programmable filter instance or the second programmable filter instance comprises a first transconductance and a second transconductance, the first transconductance having an input coupled to the receive path and an output coupled to an input of the second transconductance, wherein an output of the second transconductance is coupled to the receive path and the input of the first transconductance.

15. The programmable filter of any of clauses 1 through 14, wherein the first programmable filter instance or the second programmable filter instance further comprises a back-to-back negative gm coupled to the adjustable active inductance.

16. A method for filtering a communication signal, comprising:

selectively coupling a programmable filter to a signal receive path;

setting a first programmable filter instance of the programmable filter to a first frequency; and

setting a second programmable filter instance of the programmable filter to a second frequency such that the first programmable filter instance operates to filter the first frequency and the second programmable filter instance operates to filter the second frequency simultaneously.

17. The method of clause 16, wherein the first frequency is different than the second frequency.

18. The method of clause 16, wherein the first frequency is the same as the second frequency.

19. The method of clause 18, wherein the first frequency being the same as the second frequency increases attenuation at a selected frequency.

20. The method of clause 16, wherein the first frequency and the second frequency are sufficiently close to create a communication signal stop band.

21. The method of any of clauses 16 through 20, further comprising filtering one or more of an aggressor signal in the receive path and a victim signal in the receive path.

22. A device, comprising:

first programmable notch filtering means located between a low noise amplifier (LNA) and a mixer, the first programmable notch filtering means for filtering a signal at a first frequency selectable based on a first control signal; and

second programmable notch filtering means located between the LNA and the mixer, the second programmable notch filtering means for filtering the signal at a second frequency selectable based on a second control signal.

23. The device of clause 22, further comprising means for setting the first frequency to a frequency that is different than the second frequency.

24. The device of clause 22, further comprising means for setting the first frequency to a frequency that is the same as the second frequency.

25. The device of clause 22, further comprising means for setting the first frequency and the second frequency sufficiently close to create a communication signal stop band.

26. The device of any of clauses 22 through 25, wherein the first programmable notch filtering means and the second programmable notch filtering means are configured for filtering one or more of an aggressor signal in a receive path and a victim signal in a receive path.

27. A receiver circuit, comprising:

a receive path including a low noise amplifier (LNA) and downconversion mixer, the receive path further comprising a plurality of independently reconfigurable notch filter instances coupled in series in the receive path between the LNA and the downconversion mixer.

28. The receiver circuit of clause 27, wherein the plurality of independently reconfigurable notch filter instances are configured to provide a first filter response at a first selected frequency and a second filter response at a second selected frequency.

29. The receiver circuit of any of clauses 27 through 28, wherein the first selected frequency and the second selected frequency are the same frequency or different frequencies.

30. The receiver circuit of any of clauses 27 through 29, wherein the plurality of independently configurable notch filter instances comprises at least three (3) notch filter instances.

An apparatus implementing the circuit described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

As used in this description, the terms “component,” “database,” “module,” “system,” and the like are intended to refer to a computer-related entity, either hardware, firmware, a combination of hardware and software, software, or software in execution. For example, a component may be, but is not limited to being, a process running on a processor, a processor, an object, an executable, a thread of execution, a program, and/or a computer. By way of illustration, both an application running on a computing device and the computing device may be a component. One or more components may reside within a process and/or thread of execution, and a component may be localized on one computer and/or distributed between two or more computers. In addition, these components may execute from various computer readable media having various data structures stored thereon. The components may communicate by way of local and/or remote processes such as in accordance with a signal having one or more data packets (e.g., data from one component interacting with another component in a local system, distributed system, and/or across a network such as the Internet with other systems by way of the signal).

Although selected aspects have been illustrated and described in detail, it will be understood that various substitutions and alterations may be made therein without departing from the spirit and scope of the present invention, as defined by the following claims.

What is claimed is:

1. A programmable filter, comprising:
a first programmable filter instance comprising a first adjustable active inductance capacitively coupled to a signal receive path, the capacitive coupling comprising at least one adjustable capacitance, the adjustable active inductance and the at least one adjustable capacitance configurable to provide a filter response at a first selected frequency; and
a second programmable filter instance comprising a second adjustable active inductance capacitively coupled to the signal receive path, the capacitive coupling comprising at least one adjustable capacitance, the second adjustable active inductance and the at least one adjustable capacitance configurable to provide a filter response at a second selected frequency.

2. The programmable filter of claim 1, wherein the first selected frequency is different than the second selected frequency.

3. The programmable filter of claim 1, wherein the first selected frequency is the same as the second selected frequency.

4. The programmable filter of claim 3, wherein the first selected frequency being the same as the second selected frequency increases attenuation at the first and second selected frequency.

5. The programmable filter of claim 1, wherein the first selected frequency and the second selected frequency are sufficiently close to create a communication signal stop band.

6. The programmable filter of claim 1, wherein the programmable filter is implemented in at least one aggressor signal receive path, at least one victim signal receive path or in both an aggressor signal receive path and a victim signal path.

7. The programmable filter of claim 1, further comprising a switch network configured to selectively couple the programmable filter to a receive path one of before or after a low noise amplifier (LNA).

8. The programmable filter of claim 1, further comprising a switch network configured to selectively couple the programmable filter to one or more receive paths.

9. The programmable filter of claim 1, wherein the programmable filter is coupled between an output of a low noise amplifier (LNA) and an input of a mixer.

10. The programmable filter of claim 9, wherein the LNA, the programmable filter, and the mixer are implemented on a chip, and wherein a signal path between an input of the chip and an output of the programmable filter is inductorless.

11. The programmable filter of claim 1, wherein the programmable filter includes three (3) or more programmable filter instances.

12. The programmable filter of claim 1, wherein the programmable filter includes at least five (5) programmable filter instances.

13. The programmable filter of claim 1, wherein the programmable filter is disposed in a receive path configured to implement E-UTRAN New Radio Dual Connectivity.

14. The programmable filter of claim 1, wherein the adjustable active inductance of the first programmable filter instance or the second programmable filter instance comprises a first transconductance and a second transconductance, the first transconductance having an input coupled to the receive path and an output coupled to an input of the second transconductance, wherein an output of the second transconductance is coupled to the receive path and the input of the first transconductance.

15. The programmable filter of claim 1, wherein the first programmable filter instance or the second programmable filter instance further comprises a back-to-back negative gm coupled to the adjustable active inductance.

16. A method for filtering a communication signal, comprising:
selectively coupling a programmable filter to a signal receive path;
setting a first programmable filter instance of the programmable filter to a first frequency; and
setting a second programmable filter instance of the programmable filter to a second frequency such that the first programmable filter instance operates to filter the first frequency and the second programmable filter instance operates to filter the second frequency simultaneously.

17. The method of claim 16, wherein the first frequency is different than the second frequency.

18. The method of claim 16, wherein the first frequency is the same as the second frequency.

19. The method of claim 18, wherein the first frequency being the same as the second frequency increases attenuation at a selected frequency.

20. The method of claim 16, wherein the first frequency and the second frequency are sufficiently close to create a communication signal stop band.

21. The method of claim 16, further comprising filtering one or more of an aggressor signal in the receive path and a victim signal in the receive path.

22. A device, comprising:
first programmable notch filtering means located between a low noise amplifier (LNA) and a mixer, the first programmable notch filtering means for filtering a signal at a first frequency selectable based on a first control signal; and
second programmable notch filtering means located between the LNA and the mixer, the second programmable notch filtering means for filtering the signal at a second frequency selectable based on a second control signal.

23. The device of claim 22, further comprising means for setting the first frequency to a frequency that is different than the second frequency.

24. The device of claim 22, further comprising means for setting the first frequency to a frequency that is the same as the second frequency.

25. The device of claim 22, further comprising means for setting the first frequency and the second frequency sufficiently close to create a communication signal stop band.

26. The device of claim 22, wherein the first programmable notch filtering means and the second programmable notch filtering means are configured for filtering one or more of an aggressor signal in a receive path and a victim signal in a receive path.

27. A receiver circuit, comprising:
a receive path including a low noise amplifier (LNA) and downconversion mixer, the receive path further comprising a plurality of independently reconfigurable notch filter instances coupled in series in the receive path between the LNA and the downconversion mixer.

28. The receiver circuit of claim 27, wherein the plurality of independently reconfigurable notch filter instances are configured to provide a first filter response at a first selected frequency and a second filter response at a second selected frequency.

29. The receiver circuit of claim 28, wherein the first selected frequency and the second selected frequency are the same frequency or different frequencies.

30. The receiver circuit of claim 27, wherein the plurality of independently configurable notch filter instances comprises at least three (3) notch filter instances.
